(19) United States
(12) Patent Application Publication
(10) Pub. No.: US 2007/0075372 A1
(43) Pub. Date: Apr. 5, 2007

(54) Semiconductor device and manufacturing process therefor

(75) Inventors: Koichi Terashima, Tokyo (JP); Kiyoshi Takeuchi, Tokyo (JP); shigeharu Yamagami, Tokyo (JP); Hitoshi Wakabayashi, Tokyo (JP); Atsushi Ogura, Tokyo (JP); Koji Watanabe, Tokyo (JP); Toru Tatsumi, Tokyo (JP); Koichi Takeda, Tokyo (JP); Masahiro Nomura, Tokyo (JP); Masayasu Tanaka, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 10/576,412

(22) PCT Filed: Oct. 19, 2004
(86) PCT No.: PCT/JP04/15405

§ 371 Date: Apr. 19, 2006

(30) Foreign Application Priority Data
Oct. 20, 2003 (JP) 2003-359262
Oct. 6, 2004 (JP) 2004-294133

(51) Int. Cl. H01L 23/62

(52) U.S. Cl. 257/360

(57) ABSTRACT

There is provided a semiconductor device wherein at least the largest width of a source/drain region is larger than the width of a semiconductor region and the source/drain region has a slope having a width continuously increasing from the uppermost side to the substrate side, and a silicide film is formed in the surface of the slope.

### TECHNICAL FIELD

This invention relates to a semiconductor device having a fin-type field effect transistor with a lower contact resistance in which a contact hole can be easily aligned.

### BACKGROUND OF THE INVENTION

There has been developed a fin-type MIS type field effect transistor (hereinafter, referred to as “MISFET”) having a protrusion consisting of a semiconductor region in which a main channel is formed in planes (lateral sides of the protrusion) substantially perpendicular to a substrate. A fin-type MISFET is known to be advantageous in terms of size reduction as well as improvement in various properties such as improvement in cutoff properties or carrier mobility and reduction in short channel effect and punch-through.

Japanese Patent Application No. 1989-8670 has disclosed a fin-type MISFET in which a part of a cuboid semiconductor is a part of a silicon wafer substrate and a fi-type MISFET in which a part of a cuboid semiconductor is a part of a monocrystal silicon layer in an SOI substrate. The structures of the former and the latter will be described with reference to FIGS. 1(a) and (b), respectively.

In the structure shown in FIG. 1(a), a part of a silicon wafer substrate 101 is a cuboid 103, and a gate electrode 105 extends to both sides, passing over the top of the cuboid 103. In this cuboid 103, a channel is formed below an insulating film 104 under the gate electrode. A channel width corresponds to twice as large as the height of the cuboid 103(h), and a gate length corresponds to the width of the gate electrode 105(L). The gate electrode 105 is formed on an insulating film 102 formed in this trench such that it strides over the cuboid 103.

In the structure shown in FIG. 1(b), an SOI substrate consisting of a silicon wafer substrate 111, an insulating film 112 and a silicon monocrystal layer is prepared; the silicon monocrystal layer is patterned to form a cuboid 113; and then a gate electrode 115 is formed on the exposed insulating layer 112 such that the electrode strides over the cuboid 113. In this cuboid 113, a source and a drain regions are formed in both sides of the gate electrode, and a channel is formed below the insulating film 114 (the upper and the sides of the protrusion 113) under the gate electrode. A channel width corresponds to the sum of twice the length of height (a) and the width (b) of the cuboid semiconductor area 113, and a gate length corresponds to the width of the gate electrode 115(L).

Japanese Patent Application No. 2002-118255 has disclosed a multi-structural fin-type MOSFET having a plurality of cuboid semiconductor protrusions (protruding semiconductor layers 213) as illustrated in FIGS. 2(a) to (c). FIG. 2(b) is a cross-sectional view taken on line B-B in FIG. 2(a), while FIG. 2(c) is a cross-sectional view taken on line C-C in FIG. 2(a). This fin-type MOSFET has a plurality of protruding semiconductor layers 213 constituted by a part of a well layer 211 in the silicon substrate 210; these are aligned in parallel with each other; and a gate electrode 216 is formed such that the gate electrode 216 strides over the centers of these protruding semiconductor layers. The gate electrode 216 is formed from the upper surface of the insulating film 214 and along the side of each of the protruding semiconductor layers 213. An insulating film 218 intervenes between each protruding semiconductor layer and each gate electrode, and a channel 215 is formed in a protruding semiconductor layer under the gate electrode. Furthermore, each protruding semiconductor layer has a source/drain region, and in a region 212 under the source/drain region 217 is formed a high-concentration dopant layer (punch-through stopper layer). There are formed upper-layer interconnects 229, 230 via an interlayer insulating film 226, and each contact plug 228 connects the upper-layer interconnects with the source/drain region 217 and the gate electrode 216, respectively. Each source/drain area is connected to a common source/drain electrode 229.

Japanese Patent Application No. 2001-298194 has disclosed a fin-type MOSFET, for example, as shown in FIGS. 3(a) and (b). This fin-type MOSFET has an SOI substrate consisting of a silicon substrate 301, an insulating layer 302 and a semiconductor layer (monocrystal silicon layer) 303, and the patterned semiconductor layer 303 is formed over the insulating layer 302. The semiconductor layer 303 has a plurality of openings 310 which are aligned, cutting across the semiconductor layer 303. These openings 310 are formed such that the insulating layer 302 is exposed during patterning the semiconductor layer 303. A gate electrode 305 is formed along the alignment direction of the openings 310 striding over the centers of the openings 310. An insulating film intervenes between each semiconductor layer (conduction path) 332 and the gate electrode between the openings 310; and a channel is formed in the conduction path under the gate electrode. When the insulating film as the upper surface of the conduction path 332 is a gate insulating film as thin as the side insulating film, channels are formed in both sides and the upper surface of the semiconductor layer 332 under the gate electrode. In the semiconductor layer 303, both sides of the row of the openings 310 constitute source/drain regions 304. Source/drain regions 304 communicated to individual conducting paths are common and form a pair of source/drain regions 304 as a whole.

### SUMMARY OF THE INVENTION

In order to reduce a contact resistance, there has been proposed an MISFET having a silicide film on a source/drain region, where the silicide film is formed by sputtering. However, a fin-type MISFET described in patent references 1 to 3 has a substantially cuboid source/drain region whose lateral sides are mainly perpendicular to a substrate, so that the silicide film cannot be formed on the lateral sides by sputtering. If CVD is used to form a silicide film on the lateral sides, it may lead to defective deposition such as facet formation or the whole source/drain region may be silicided. Thus, silicide formation may not effectively reduce a contact resistance. Furthermore, as a semiconductor device has been highly integrated, an MISFET has been size-reduced. It, therefore, becomes difficult to align a contact hole with a source/drain region in the MISFET.

In view of the above situation, this invention provides a semiconductor device having a fin-type MISFET, wherein a source/drain region has a width larger than a width of a protruding semiconductor region where a channel is to be formed and has a slope whose width continuously increases from the uppermost side to the substrate side or a concavity and convexity portion where a cross-sectional area continuously increases. Having such a slope or a concavity and convexity portion, a semiconductor device of this invention allows a silicide film to be formed in a larger area than a conventional fin-type MISFET.

An objective of this invention is to facilitate alignment during forming a contact hole on a source/drain region and to reduce a contact resistance by reducing a parasitic resistance in the source/drain region by employing the above configuration. Another objective is to provide a process for manufacturing such a semiconductor device.

To solve the above problems, this invention has the following configuration. In an aspect of the present invention, there is provided a semiconductor device comprising a protruding semiconductor region formed on a substrate, a protruding source/drain region sandwiching the semiconductor region and a gate electrode formed at least on lateral sides of the semiconductor region via an insulating film,

wherein the source/drain region has a slope in which at least the largest width is larger than a width of the semiconductor region and width continuously increases from the uppermost side to the substrate side in the source/drain region, and a silicide film is formed on the surface of the slope.

In another aspect of the present invention, there is provided a semiconductor device comprising a plurality of protruding semiconductor regions formed on a substrate, a plurality of source/drain regions sandwiching the semiconductor regions and a gate electrode formed at least on lateral sides of the semiconductor regions via an insulating film,

wherein the plurality of semiconductor regions are aligned in a direction perpendicular to a channel current flow and in parallel with each other, and the gate electrode strides over the plurality of semiconductor regions and extends in a direction perpendicular to the channel current flow,

wherein the source/drain regions have slopes in which at least the largest width is larger than a width of the semiconductor region and width continuously increases from the uppermost side to the substrate side in the source/drain regions, and a silicide film is formed on the surface of the slopes.

In another aspect of the present invention, there is provided a semiconductor device comprising a plurality of protruding semiconductor regions formed on a substrate, a paired protruding source/drain region which is common to the plurality of semiconductor regions and sandwiches the plurality of semiconductor regions, and a gate electrode formed at least on lateral sides of the plurality of semiconductor regions via an insulating film,

wherein the plurality of semiconductor regions are aligned in a direction perpendicular to a channel current flow and in parallel with each other, and the gate electrode strides over the plurality of semiconductor regions and extends in a direction perpendicular to the channel current flow,

wherein the source/drain region has a concavity and convexity portion in which a cross-sectional area continuously increases from the uppermost side to the substrate side, and a silicide film is formed on the surface of the concavity and convexity portion.

In the present invention, it is preferable that the concavity and convexity portion are formed in the direction of alignment of the plurality of semiconductor regions at the same regular intervals as the plurality of semiconductor regions such that the semiconductor regions are in parallel with the concavity and convexity portion.

In the present invention, it is also preferable that the uppermost side of the source/drain region(s) is parallel with a plane of the substrate and a silicide film is formed on the uppermost side.

In the present invention, it is also preferable that the whole of the source/drain region(s) is composed from the slope(s) having a silicide film on its surface.

In the present invention, it is also preferable that a width of the slope(s) in the source/drain region(s) increases from the uppermost side to the substrate side in a constant rate.

In the present invention, it is also preferable that the cross-sectional area of the concavity and convexity portion increases from the uppermost side to the substrate side in a constant rate.

In another aspect of the present invention, there is provided a process for manufacturing a semiconductor device comprising a field effect transistor having a protruding semiconductor region in whose lateral sides a channel is formed, comprising

(a) forming a protruding source/drain region sandwiching the protruding semiconductor region with a gate electrode by selective epitaxial growth to make a slope in which a width of the source/drain region is larger than a width of the semiconductor region and continuously increases from the uppermost side to the substrate side in the source/drain region, and (b) forming a silicide film on the surface of the slope.

In another aspect of the present invention, there is provided a process for manufacturing a semiconductor device comprising a field effect transistor having a plurality of protruding semiconductor regions in whose lateral sides a channel is formed, comprising

(a) forming a gate electrode striding over the plurality of protruding semiconductor regions, then forming a plurality of protruding source/drain regions sandwiching the plurality of semiconductor regions by selective epitaxial growth to make slopes in which a width of the source/drain regions is larger than a width of the semiconductor regions and continuously increases from the uppermost side to the substrate side in the source/drain regions, and (b) forming a silicide film on the surface of the slopes.

In another aspect of the present invention, there is provided a process for manufacturing a semiconductor device comprising a field effect transistor having a plurality of protruding semiconductor regions in whose lateral sides a channel is formed, comprising

(a) forming a gate electrode striding over the plurality of protruding semiconductor regions, then forming a plurality of protruding source/drain regions sandwiching the plurality of semiconductor regions by selective epitaxial growth until adjacent source/drain regions come into contact each other to make a concavity and convexity portion where a cross-sectional area of the source/drain regions continuously increase from the uppermost side to the substrate side in the source/drain regions during the selective epitaxial growth, and (b) forming a silicide film on the surface of the concavity and convexity portion.

In this invention, it is also preferable that the slope(s) is formed by selective epitaxial growth in substantially up to eight crystal faces in a cross section which is in parallel with the width direction and with the direction from the uppermost side to the substrate side of the source/drain region(s) and intersects with the uppermost side.

In this invention, it is also preferable that the concavity and convexity portion are formed by selective epitaxial growth in substantially up to eight crystal faces in a cross section which is in parallel with the width direction and with the direction from the uppermost side to the substrate side of the source/drain regions and intersects with the uppermost side.

In this invention, it is also preferable that the slope(s) is formed by selective epitaxial growth as a substantially curve in a cross section which is in parallel with the width direction and with the direction from the uppermost side to the substrate side of the source/drain region(s) and intersects with the uppermost side.

In this invention, it is also preferable that the concavity and convexity portion are formed by selective epitaxial growth as a substantially curve in a cross section which is in parallel with the width direction and with the direction from the uppermost side to the substrate side of the source/drain regions and intersects with the uppermost side.

In another aspect of the present invention, there is provided a process for manufacturing a semiconductor device comprising a field effect transistor having a protruding semiconductor region in whose lateral sides a channel is formed, comprising,

(a) forming a gate electrode on the protruding semiconductor region and then etching a protruding source/drain region sandwiching the semiconductor region and having a larger width than the width of the semiconductor region, to make a slope in which a width of the source/drain region is larger than a width of the semiconductor region and continuously increases from the uppermost side to the substrate side in the source/drain region, and (b) forming a silicide film on the surface of the slope.

In another aspect of the present invention, there is provided a process for manufacturing a semiconductor device comprising a field effect transistor having a plurality of protruding semiconductor regions in whose lateral sides a channel is formed, comprising,

(a) forming a gate electrode striding over the plurality of protruding semiconductor regions, forming a paired protruding source/drain region sandwiching the plurality of semiconductor regions, and then forming a mask film having a plurality of openings alternately with the plurality of semiconductor regions along the alignment direction of the semiconductor regions on the source/drain region, (b) conducting etching using the mask film to make the paired source/drain region into a plurality of source/drain regions mutually separated sandwiching the plurality of semiconductor regions and during the etching, making slopes in which a width of the source/drain regions is larger than a width of the semiconductor regions and continuously increases from the uppermost side to the substrate side in the source/drain regions, and (c) forming a silicide film on the slopes.

In another aspect of the present invention, there is provided a process for manufacturing a semiconductor device comprising a field effect transistor having a plurality of protruding semiconductor regions in whose lateral sides a channel is formed, comprising,

(a) forming a gate electrode striding over the plurality of protruding semiconductor regions, forming a paired protruding source/drain region sandwiching the plurality of semiconductor regions, and then forming a mask film having a plurality of openings alternately with the plurality of semiconductor regions along the alignment direction of the semiconductor regions on the source/drain region, (b) conducting etching using the mask film to make a concavity and convexity portion in which cross-sectional area continuously increases from the uppermost side to the substrate side in the source/drain region, and (c) forming a silicide film on the concavity and convexity portion.

In this invention, it is preferable that the etching is wet etching.

In this invention, it is also preferable that the substrate is an insulating film layer, on which the protruding semiconductor region(s) and the protruding source/drain region(s) are formed.

In this invention, it is also preferable that the substrate is an interlayer insulating film, and

the protruding semiconductor region(s) and the protruding source/drain region(s) are parts of the semiconductor layer formed under the interlayer insulating film, which penetrates the interlayer insulating film and protrudes above the interlayer insulating film.

Preferably, the semiconductor device of this invention further comprising a planar type field effect transistor having a semiconductor region on whose upper surface a main channel is formed, and an elevated source/drain region.

This invention can provide a semiconductor device having a fin-type MISFET, which has a slope or a concavity and convexity portion in a source/drain region whereby a contact resistance is reduced and a contact hole can be easily aligned, as well as a process for manufacturing such a device.

In this invention, there is made a slope or a concavity and convexity portion where a silicide film is formed over the whole surface of the source/drain region, so that the silicide film is allowed to be formed in a larger area. As a result, a contact hole can be more easily aligned and a parasitic resistance can be more effectively reduced.

In this invention, there is a plane parallel with a substrate plane in the uppermost side in a source/drain region, which allows a thicker suicide film to be formed, resulting in more effective reduction of a parasitic resistance.

In this invention, a multi-structural MISFET may have s source/drain region having a slope or a concavity and convexity portion, which allows a silicide film to be formed in a larger area and facilitates alignment of a contact hole in comparison with a single-structural MISFET.

### BRIEF DESCRIPTION OF THE DRAWINGS

FIG. 1(a) illustrates a conventional single-structural fin-type MISFET. FIG. 1(b) illustrates a conventional single-structural fin-type MISFET.

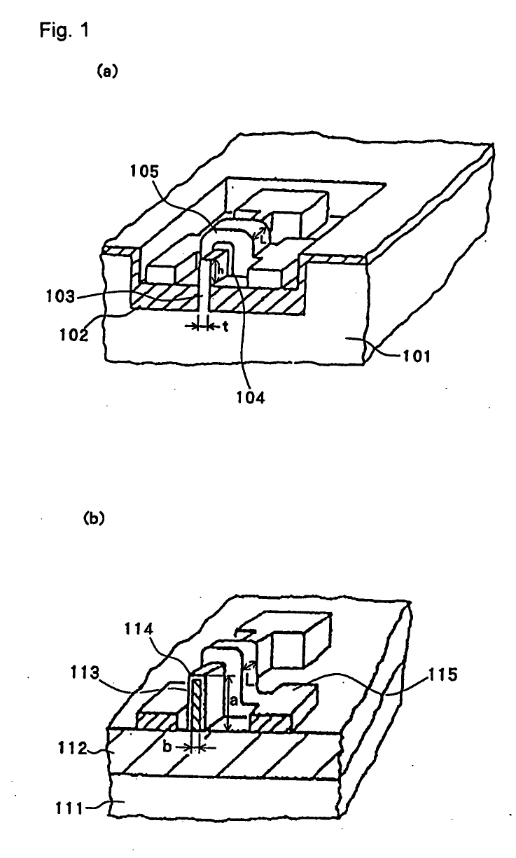

FIG. 2(a) illustrates a conventional multi-structural fin-type MISFET. FIG. 2(b) illustrates a conventional multi-structural fin-type MISFET. FIG. 2(c) illustrates a conventional multi-structural fin-type MISFET.

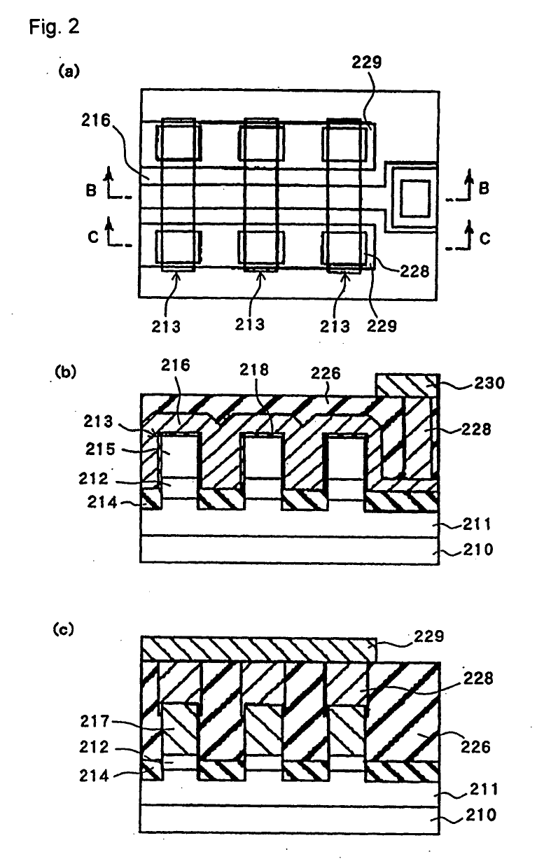

FIG. 3(a) illustrates a conventional multi-structural fin-type MISFET. FIG. 3(b) illustrates a conventional multi-structural fin-type MISFET.

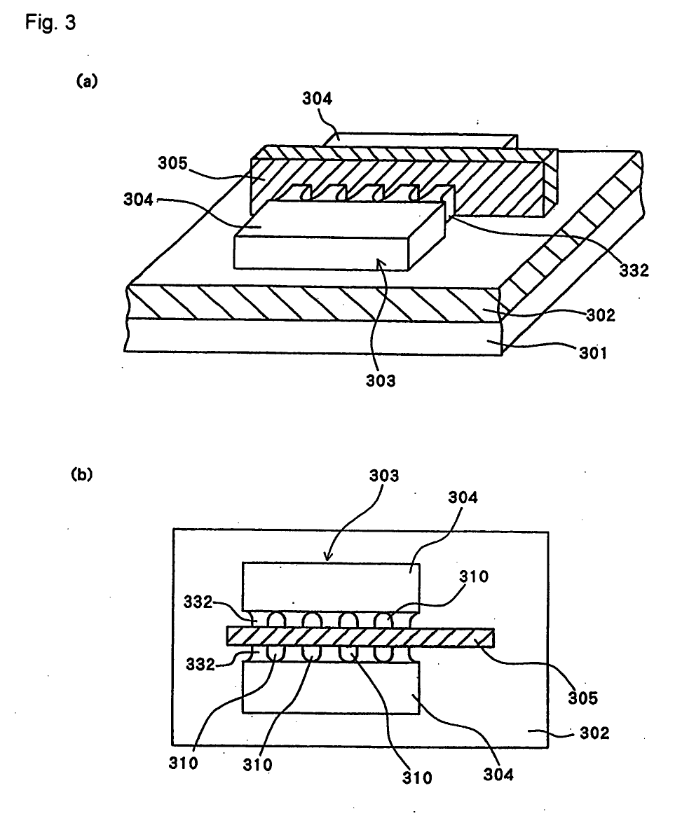

FIG. 4(a) illustrates an example of a semiconductor device of this invention. FIG. 4(b) illustrates an example of a semiconductor device of this invention.

FIG. 5(a) illustrates an example of a semiconductor device of this invention. FIG. 5(b) illustrates an example of a semiconductor device of this invention. FIG. 5(c) illustrates an example of a semiconductor device of this invention.

FIG. 6(a) illustrates an example of a semiconductor device of this invention. FIG. 6(b) illustrates an example of a semiconductor device of this invention. FIG. 6(c) illustrates an example of a semiconductor device of this invention. FIG. 6(d) illustrates an example of a semiconductor device of this invention. FIG. 6(e) illustrates an example of a semiconductor device of this invention. FIG. 6(f) illustrates an example of a semiconductor device of this invention.

FIG. 7(a) illustrates an example of a semiconductor device of this invention. FIG. 7(b) illustrates an example of a semiconductor device of this invention. FIG. 7(c) illustrates an example of a semiconductor device of this invention. FIG. 7(d) illustrates an example of a semiconductor device of this invention.

FIG. 8(a) illustrates an example of a semiconductor device of this invention. FIG. 8(b) illustrates an example of a semiconductor device of this invention. FIG. 8(c) illustrates an example of a semiconductor device of this invention. FIG. 8(d) illustrates an example of a semiconductor device of this invention.

FIG. 9(a) illustrates an example of a semiconductor device of this invention. FIG. 9(b) illustrates an example of a semiconductor device of this invention. FIG. 9(c) illustrates an example of a semiconductor device of this invention.

FIG. 10(a) illustrates an example of a semiconductor device of this invention. FIG. 10(b) illustrates an example of a semiconductor device of this invention. FIG. 10(c) illustrates an example of a semiconductor device of this invention.

FIG. 11(a) illustrates a process for manufacturing a semiconductor device of this invention. FIG. 11(b) illustrates a process for manufacturing a semiconductor device of this invention. FIG. 11(c) illustrates a process for manufacturing a semiconductor device of this invention. FIG. 11(d) illustrates a process for manufacturing a semiconductor device of this invention. FIG. 11(e) illustrates a process for manufacturing a semiconductor device of this invention. FIG. 11(f) illustrates a process for manufacturing a semiconductor device of this invention.

FIG. 12(a) illustrates a process for manufacturing a semiconductor device of this invention. FIG. 12(b) illustrates a process for manufacturing a semiconductor device of this invention. FIG. 12(c) illustrates a process for manufacturing a semiconductor device of this invention. FIG. 12(d) illustrates a process for manufacturing a semiconductor device of this invention.

FIG. 13(a) illustrates a process for manufacturing a semiconductor device of this invention. FIG. 13(b) illustrates a process for manufacturing a semiconductor device of this invention. FIG. 13(c) illustrates a process for manufacturing a semiconductor device of this invention. FIG. 13(d) illustrates a process for manufacturing a semiconductor device of this invention.

FIG. 14(a) illustrates a process for manufacturing a semiconductor device of this invention. FIG. 14(b) illustrates a process for manufacturing a semiconductor device of this invention. FIG. 14(c) illustrates a process for manufacturing a semiconductor device of this invention. FIG. 14(d) illustrates a process for manufacturing a semiconductor device of this invention.

FIG. 15(a) illustrates a process for manufacturing a semiconductor device of this invention. FIG. 15(b) illustrates a process for manufacturing a semiconductor device of this invention. FIG. 15(c) illustrates a process for manufacturing a semiconductor device of this invention. FIG. 15(d) illustrates a process for manufacturing a semiconductor device of this invention. FIG. 15(e) illustrates a process for manufacturing a semiconductor device of this invention. FIG. 15(f) illustrates a process for manufacturing a semiconductor device of this invention. FIG. 15(g) illustrates a process for manufacturing a semiconductor device of this invention. FIG. 15(h) illustrates a process for manufacturing a semiconductor device of this invention.

FIG. 16(a) illustrates a process for manufacturing a semiconductor device of this invention. FIG. 16(b) illustrates a process for manufacturing a semiconductor device of this invention. FIG. 16(c) illustrates a process for manufacturing a semiconductor device of this invention. FIG. 16(d) illustrates a process for manufacturing a semiconductor device of this invention. FIG. 16(e) illustrates a process for manufacturing a semiconductor device of this invention. FIG. 16(f) illustrates a process for manufacturing a semiconductor device of this invention. FIG. 16(g) illustrates a process for manufacturing a semiconductor device of this invention.

FIG. 17(a) illustrates a process for manufacturing a semiconductor device of this invention. FIG. 17(b) illustrates a process for manufacturing a semiconductor device of this invention. FIG. 17(c) illustrates a process for manufacturing a semiconductor device of this invention. FIG. 17(d) illustrates a process for manufacturing a semiconductor device of this invention.

FIG. 18(a) illustrates a process for manufacturing a semiconductor device of this invention. FIG. 18(b) illustrates a process for manufacturing a semiconductor device of this invention. FIG. 18(c) illustrates a process for manufacturing a semiconductor device of this invention. FIG. 18(d) illustrates a process for manufacturing a semiconductor device of this invention.

FIG. 19(a) illustrates a process for manufacturing a semiconductor device of this invention. FIG. 19(b) illustrates a process for manufacturing a semiconductor device of this invention. FIG. 19(c) illustrates a process for manufacturing a semiconductor device of this invention. FIG. 19(d) illustrates a process for manufacturing a semiconductor device of this invention. FIG. 19(e) illustrates a process for manufacturing a semiconductor device of this invention. FIG. 19(f) illustrates a process for manufacturing a semiconductor device of this invention. FIG. 19(g) illustrates a process for manufacturing a semiconductor device of this invention. FIG. 19(h) illustrates a process for manufacturing a semiconductor device of this invention.

FIG. 20(a) illustrates a process for manufacturing a semiconductor device of this invention. FIG. 20(b) illustrates a process for manufacturing a semiconductor device of this invention.

FIG. 21(a) illustrates a process for manufacturing a semiconductor device of this invention. FIG. 21(b) illustrates a process for manufacturing a semiconductor device of this invention. FIG. 21(c) illustrates a process for manufacturing a semiconductor device of this invention.

FIG. 22(a) illustrates a semiconductor device of this invention. FIG. 22(b) illustrates a semiconductor device of this invention. FIG. 22(c) illustrates a semiconductor device of this invention. FIG. 22(d) illustrates a semiconductor device of this invention.

FIG. 23(a) illustrates a semiconductor device of this invention. FIG. 23(b) illustrates a semiconductor device of this invention. FIG. 23(c) illustrates a semiconductor device of this invention. FIG. 23(d) illustrates a semiconductor device of this invention.

FIG. 24(a) illustrates a process for manufacturing a semiconductor device of this invention. FIG. 24(b) illustrates a process for manufacturing a semiconductor device of this invention. FIG. 24(c) illustrates a process for manufacturing a semiconductor device of this invention.

FIG. 25(a) illustrates a process for manufacturing a semiconductor device of this invention. FIG. 25(b) illustrates a process for manufacturing a semiconductor device of this invention. FIG. 25(c) illustrates a process for manufacturing a semiconductor device of this invention.

### DETAILED DESCRIPTION OF THE INVENTION

Semiconductor Device

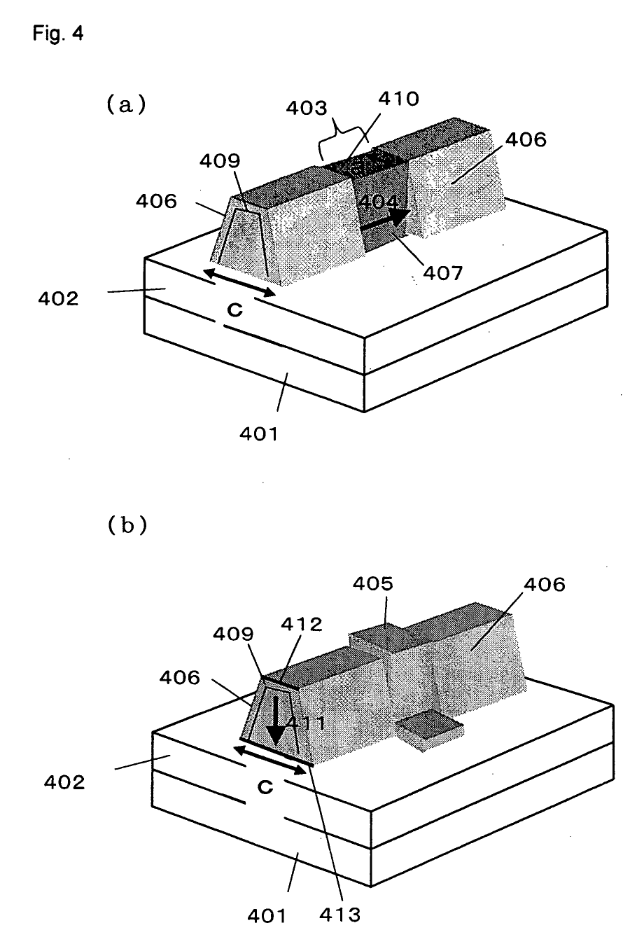

There will be described a semiconductor device according to the present invention with reference to FIG. 4. FIG. 4(b) illustrates an example of a semiconductor device of this invention. FIG. 4(a) shows a protruding semiconductor region where a source/drain region constituting a semiconductor device in FIG. 4(b) and a channel are to be formed. The semiconductor device of this invention has a protruding semiconductor region 403, which is sandwiched by a protruding source/drain region 406. On the lateral sides of the protruding semiconductor region 403 is formed a gate electrode 405 via a gate insulating film. On the source/drain region 406 is formed a silicide film 409.

The protruding semiconductor region 403 has an upper surface 410 parallel with a substrate plane (a given plane parallel to the substrate) and lateral sides 407 perpendicular to the substrate plane. The lateral sides 407 have a channel where a channel current flows in the direction of the arrow 404. The protruding semiconductor region may have a shape of a cuboid or deformed cuboid as long as processing accuracy or desired device properties are obtained. The source/drain region 406 in the MISFET of this invention has a width larger than that of the protruding semiconductor region 403 where a channel is formed, and the source/drain region has a slope whose width continuously increases from the uppermost side to the substrate side. As used herein, the phrase “from the uppermost side to the substrate side” indicates the direction 411 from the uppermost side 412 to the substrate side 413 in the source/drain region, which corresponds to the downward direction of the normal line of the substrate (insulating film) 402. Therefore, in the fin-type MISFET of this invention, a silicide film can be formed in a larger area over the source/drain region than a conventional fin-type MISFET. As a result, a contact resistance can be reduced, alignment of a contact hole on the source/drain region can be facilitated, and furthermore, a parasitic resistance of the MISFET can be reduced. The term “a width of a protruding semiconductor region” refers to a width of the protruding semiconductor region 403 in a direction perpendicular to the channel current flow direction 404 and parallel with the substrate plane (insulating film) 402 (FIG. 4(a)-a). The term “a width of a source/drain region” refers to a width of the source/drain region in a direction perpendicular to the channel current flow direction 404 and parallel with the substrate plane (insulating film) 402 (FIG. 4-c).

The MISFET of this invention may be a double-gate type where a thick gate insulating film is formed on the upper surface 410 of the protruding semiconductor region 403 and a channel is formed only on its lateral sides 407. Alternatively, it may be a tri-gate type where a thinner gate insulating film is formed on the upper surface 410 and a channel is formed also on the upper surface 410.

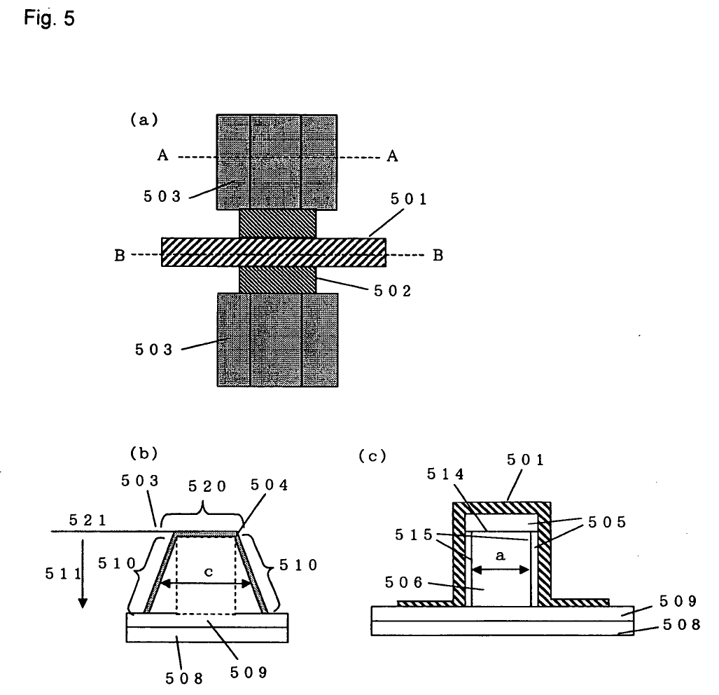

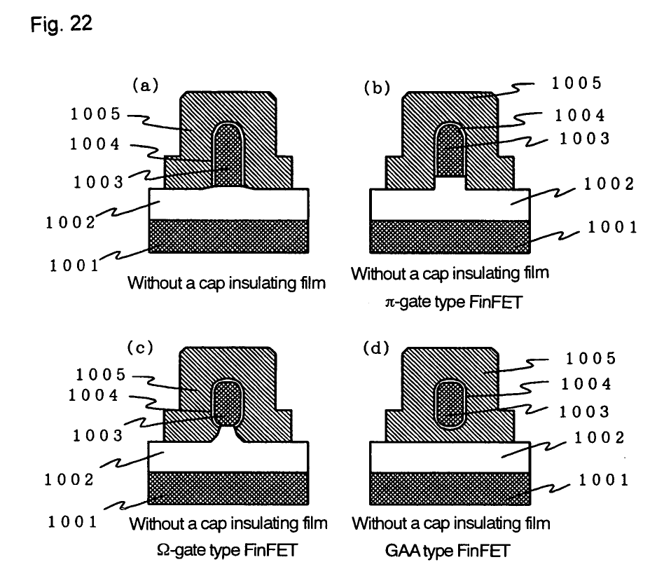

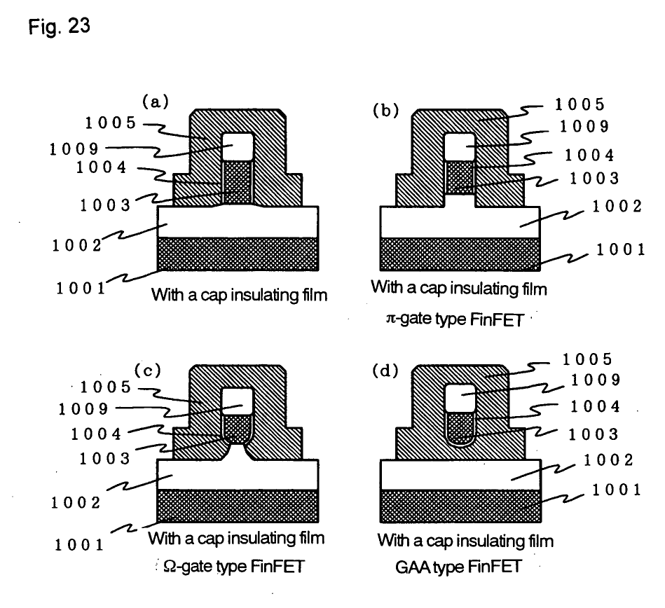

FIGS. 22 and 23 show examples of an MISFET according to this invention having various gate electrode structures. Each of FIGS. 22 and 23 corresponds to a cross-sectional view taken on line B-B in FIG. 5(a). FIG. 22 and 23 are cross-sectional views of a semiconductor device without and with a capping insulating film, respectively.

FIGS. 22(a) and 23(a) are cross-sectional views of a semiconductor device having a semiconductor region 1003 on an insulator 1002. FIGS. 22(b) and 23(b) show a structure in which the lower end of the gate electrode 1005 is lower than the lower end of the semiconductor region 1003. This structure is called a “π-gate structure” because it resembles a Greek letter “π”. When a gate electrode extends to a lower position than the protruding semiconductor region as described above, control of a channel by the gate electrode can be reinforced, and sharpness of ON-OFF transfer (subthreshold property) can be improved, resulting in prevention of an OFF current.

FIGS. 22(c) and 23(c) show a structure in which a part of a gate electrode 1005 goes around to the undersurface of a semiconductor region 1003 (a structure where a gate electrode extends such that it covers a part of the undersurface of a protruding semiconductor region). This structure is called a “Ω gate structure” because it resembles a Greek letter “Ω”. Using this structure, control of a channel by the gate electrode can be further reinforced, and the undersurface of the semiconductor region can be utilized as a channel, resulting in improvement of driving ability.

FIGS. 22(d) and 23(d) show a structure where a gate electrode 1005 completely goes around to the undersurface of the semiconductor region 1003. This structure is called as a “gate-all-around (GAA) structure” because in the lower part of the gate, the semiconductor region floats in the air in relation to the substrate plane. Using this structure, the undersurface of the semiconductor region can be also used as a channel, so that driving ability can be improved and short channel effect can be also improved.

In FIGS. 22 and 23, the upper corners of the semiconductor region may be rounded off.

A material for a gate electrode may be a conductive material having a desired conductivity and a desired work function. Examples include doped semiconductors such as doped polycrystalline silicon, polycrystalline SiGe, polycrystalline Ge and polycrystalline SiC; metals such as Mo, W, Ta, Ti, Hf, Re and Ru; metal nitrides such as TiN, TaN, HfN and WN; and suicides such as cobalt silicide, nickel silicide, platinum silicide and erbium silicide. Examples of a gate electrode structure may include, in addition to a single crystal film, lamination structures such as a laminated film of a semiconductor and a metal film, a laminated film of metal films, and a laminated film of a semiconductor and a silicide film.

A gate insulating film may be, besides an SiO₂ film and an SiON film, a so-called high-dielectric-constant insulating film (High-K film). Examples of a High-K film include metal oxides such as a Ta₂O₅ film, an A₂O₃ film, an La₂O₃ film, an HfO₂ film and a ZrO₂ film; and complex metal oxides represented by a composition formula such as HfSiO, ZrSiO, HfAlO and ZrAlO. A gate insulating film may have a laminated structure. An example is a laminated film formed by forming, on a semiconductor layer such as silicon, a silicon-containing oxide film such as SiO₂ and HfSiO, on which is then formed an High-K film.

The semiconductor region and the source/drain region in the fin-type MISFET of this invention have a structure protruding from the substrate plane. The semiconductor device of this invention may be formed using an SOI substrate. Here, as shown in FIG. 4(b), the substrate is an insulating film layer in an SOI substrate, and the protruding semiconductor region and the protruding source/drain region are made from silicon layer in the SOI substrate.

An insulating film may be SiO₂, but alternatively, for example, like an SOS (silicon on sapphire, silicon on spinel), a structure in which an insulating material under a semiconductor region itself is a supporting substrate may be used. Examples of an insulating supporting substrate include, in addition to the above SOS, quartz and an AlN substrate. A semiconductor region can be formed on such a supporting substrate by a manufacturing process for an SOI (the steps of bonding and film-thinning).

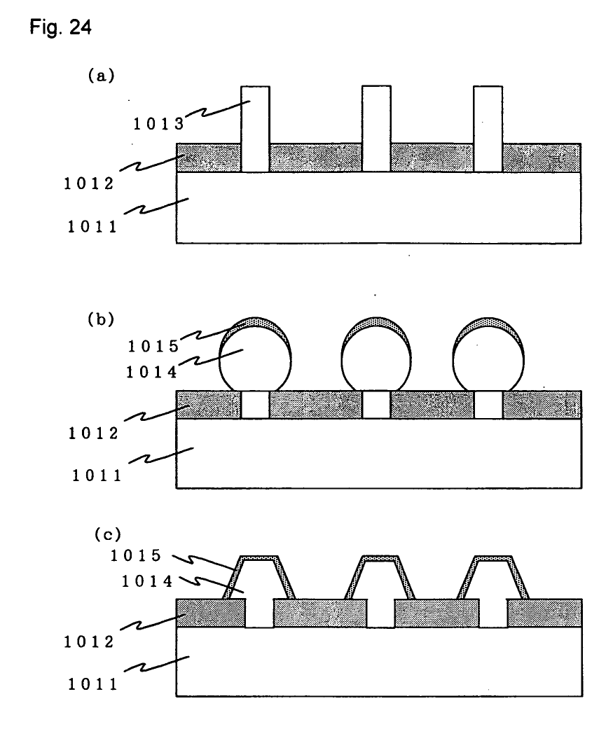

A semiconductor device of this invention may be prepared using a bulk substrate. Specifically, in this semiconductor device, an interlayer insulating film is formed on a semiconductor layer, part of which penetrates and protrudes above the interlayer insulating film to form a protruding semiconductor region and a protruding source/drain region. FIG. 24 shows an example of a semiconductor device using a bulk substrate. FIG. 24(a) illustrates a configuration where part of a semiconductor layer 1011 penetrates and protrudes above an interlayer insulating film 1012 to form a protruding semiconductor region 1013. FIGS. 24(b) and (c) show configurations where the protruding semiconductor region 1013 is selectively epitaxially grown; FIG. 24(b) shows a semiconductor device having a source/drain region with a curved cross section (a cross section corresponding to A-A direction in FIG. 5(a)) and FIG. 24(c) shows a semiconductor device having a source/drain region with a tapered cross section. Whether the shape of the cross section is curved or tapered depends on the conditions of selective epitaxial growth.

In a fin-type MISFET of this invention, main channels are preferably formed in both lateral sides of a protruding semiconductor region, and a width W of the protruding semiconductor region under the gate electrode is such a width that during operation, the region is completely depleted by depletion layers formed from the individual lateral sides of the protruding semiconductor region.

Specifically, a width W of a protruding semiconductor region under a gate electrode is preferably 5 nm or more, more preferably 10 nm or more in the light of processing accuracy and strength while being preferably 60 nm or less, more preferably 30 nm or more in the light of using a channel formed in the lateral sides of the protruding semiconductor region as a dominant channel and providing a completely depleted structure.

Specific dimensions in a fin-type MISFET having a protruding semiconductor region of this invention may be appropriately determined, for example, within the following ranges.

Width of a protruding semiconductor region (W): 5 to 100 nm,

Height of a protruding semiconductor region (H): 20 to 200 nm,

Gate length (L): 10 to 100 nm,

Thickness of a gate insulating film: 1 to 5 nm (in the case of SiO₂),

Dopant concentration in a channel forming region: 0 to 1×10¹⁹ cm⁻³,

Dopant concentration in a source/drain region: 1×10¹⁹ to 1×10²¹ cm⁻³.

A height of a protruding semiconductor region (H) refers to a length in a direction perpendicular to a substrate plane in a semiconductor protruding from a base insulating film plane. A channel forming region refers to a part of a protruding semiconductor region under a gate electrode.

A silicide film preferably contains at least one selected from the group consisting of Ti, Co, Ni, Pt, Pd, Mo, W, Zr, Hf, Ta, Ir, Al, V and Cr. A silicide film containing such elements can exhibit good conductivity, resulting in reduction of a parasitic resistance. A thickness of a silicide film is preferably 10 to 50 nm. A thickness of 10 nm or more may leads to effective reduction of a parasitic resistance. A thickness of 50 nm or less may avoid a problem that excessive siliciding reaction during annealing deteriorates device properties of a source/drain region.

### Embodiment 1

The first embodiment of this invention relates to a semiconductor device having a single-structural fin-type MISFET. A single-structural MISFET has a protruding semiconductor region and a paired source/drain region within one transistor.

The source/drain region in this embodiment may have various shapes as shape of slope as long as the source/drain region has a slope in which at least the largest width is larger than a width of the semiconductor region and width continuously increases from the uppermost side to the substrate side.

The slope of the source/drain region may be, for example, a curve where a width increases from the uppermost side to the substrate side at an inconstant rate or a taper where a width increases at a constant rate.

FIG. 5(a) is a plan view of a semiconductor device having an MISFET in which a source/drain region is tapered. FIG. 5(b) is a cross-sectional view of the semiconductor device taken on line A-A in FIG. 5(a), and FIG. 5(c) is a cross-sectional view of the semiconductor device taken on line B-B in FIG. 5(a). A semiconductor region 506 direct below a gate electrode 501 is a protrusion (typically, a cuboid) with width “a”. In this MISFET, a thick gate insulating film 505 is formed on an upper surface 514 of the protruding semiconductor region 506, and a channel is formed in lateral sides 515 of the protruding semiconductor region 506. A dot-line region in FIG. 5(b) indicates a shape with the same scale as a cross-sectional shape of the protruding semiconductor region 506 in a direction perpendicular to the plane of the substrate (insulating film) 509. In this semiconductor device, width “c” of the source/drain region is larger than width “a” of the protruding semiconductor region 506, and width “c” increases from the uppermost side 521 of the source/drain region to the side of the substrate (insulating film) 509 (the direction of the arrow 511). In FIG. 5(b), the source/drain region is tapered such that a width increases in the direction of the arrow 511 in a constant rate. The taper 510 and the upper surface 520 have a silicide film 504.

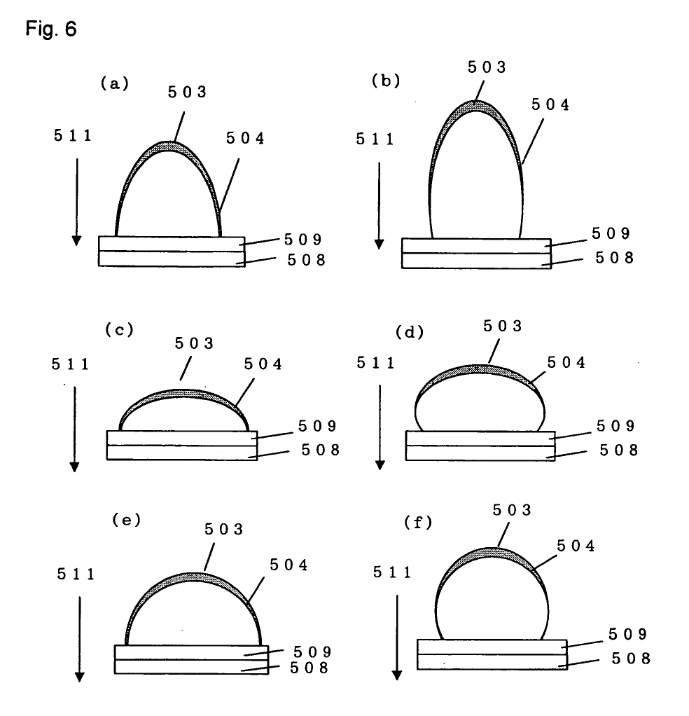

FIGS. 6 to 8 illustrate variations of the semiconductor device in FIG. 5 only in cross-sectional views of the source/drain region. FIGS. 6 to 8 show a cross section of the source/drain region from the direction corresponding to line A-A in FIG. 5(a).

FIG. 6 shows a source/drain region having a curved shape. In FIGS. 6(a) and (b), the source/drain region has an elliptical cross section whose long axis is in the same direction as the normal line of the substrate (insulating film) 509. In FIGS. 6(c) and (d), the source/drain region has an elliptical cross section whose short axis is in the same direction as the normal line of the substrate 509. In FIGS. 6(e) and (f), the source/drain region has a perfect-circular cross section. Thus, the source/drain region may have various curved shapes. In FIGS. 6(a), (c) and (e), the source/drain region has, in all parts, a width increasing from the uppermost side to the substrate side (in the direction of the arrow 511). Here, since a suicide film can be formed over the whole surface of the source/drain region, a contact hole can be more easily aligned, resulting in more effective reduction in a parasitic resistance. In FIGS. 6(b), (d) and (f), in the upper part of the source/drain region, the source/drain region has a curved shape where a width increases from the uppermost side to the substrate side (in the direction of the arrow 511) and then decreases as it comes closer to the substrate side. In such a shape, a silicide film 504 can be formed in the upper curved shape. The source/drain region may be a concave as well as a convex.

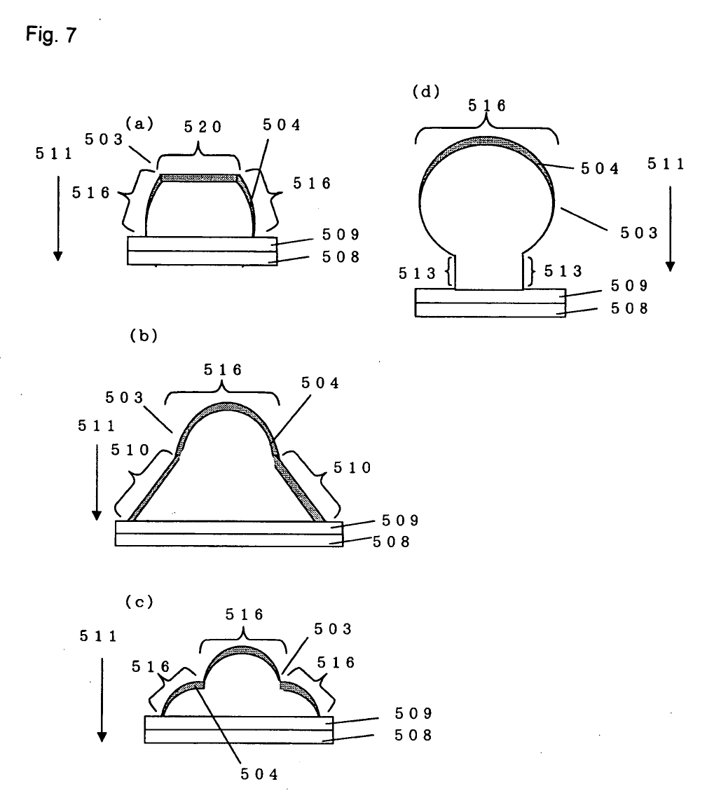

FIG. 7 shows variations of FIG. 6. In FIG. 7(a), an upper surface 520 of the source/drain region forms a plane parallel with the plane of the substrate 509 and has curves 516 in both sides. In FIG. 7(b), a part of the source/drain region has a curve 516 which has taper shapes 510 in both sides. In FIG. 7(c), the source/drain region has three curves 516. In FIG. 7(d), the source/drain region has a curve 516 and lateral sides 513 perpendicular to the substrate. As described above, the source/drain region may have two or more different curves. It may have two or more types of curves and taper shapes, or alternatively a part of the source/drain region may have a plane parallel to the substrate and a plane perpendicular to the substrate. In FIG. 7, a silicide film 504 is formed on the taper shape 510, the upper surface 520 and/or the curve 516.

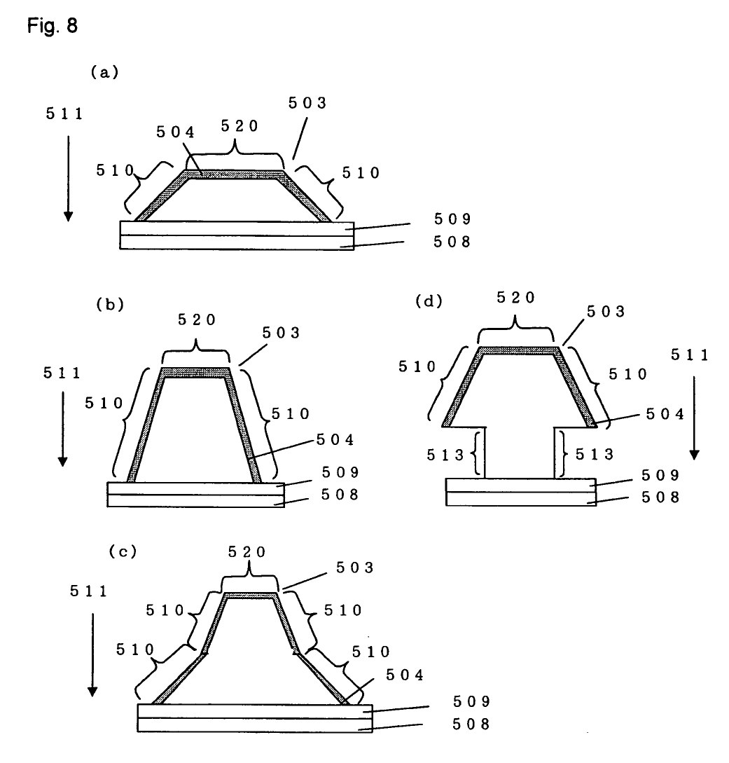

FIG. 8 shows a source/drain region having a taper shape whose width increases from the uppermost side to the substrate side (in the direction of the arrow 511) at a constant rate.

In FIG. 8(a), the source/drain region has a taper shape 510 with gentle inclination. In FIG. 8(b), the source/drain region has a taper shape 510 with sharp inclination. An inclination angle is preferably 10 to 80°, more preferably 20 to 60°, further preferably 40 to 50°. When an inclination angle is small, a thick silicide film can be formed by sputtering, while when an inclination angle is large, a substrate area occupied by the source/drain region can be reduced. Thus, when an inclination angle of the taper shape is within these ranges, a semiconductor device can be optimized in the light of a contact resistance and a plane area of a device. As used herein, the term “an inclination angle” refers to an angle from the plane of the substrate (insulating film) 509, which is defined as an angle of 90° or less. An example is a taper shape with an inclination angle of 25.2°, 54.7° or a combination of these two. In FIG. 8(c), the source/drain region has two or more taper shapes 510 with different inclination angles. In FIG. 8(d), the source/drain region has a taper shape 510 and lateral sides 513 perpendicular to the substrate. In FIG. 8, a silicide film 504 is formed on the taper shape 510 and the upper surface 520.

As shown in FIG. 8, the source/drain region may have an upper surface 520 parallel with the substrate. Thus, in the surface parallel with the substrate plane, a thick silicide film can be formed during sputtering, resulting in reduction of a parasitic resistance. A width of the upper surface parallel to the substrate may be smaller than a width of the protruding semiconductor region.

As shown in FIG. 8, the source/drain region may have a plurality of taper shapes with different inclination angles or may have a plurality of concave and convex curves. Alternatively, a part of the source/drain region may have a surface parallel with the substrate and a surface perpendicular to the substrate.

The source/drain region in the MISFET of this invention may be asymmetric with respect to a given plane parallel with the lateral sides of the protruding semiconductor. For example, one of two divisions of the source/drain region in the given plane may have a curved shape as shown in FIG. 6 while the other may have a taper shape as shown in FIG. 8.

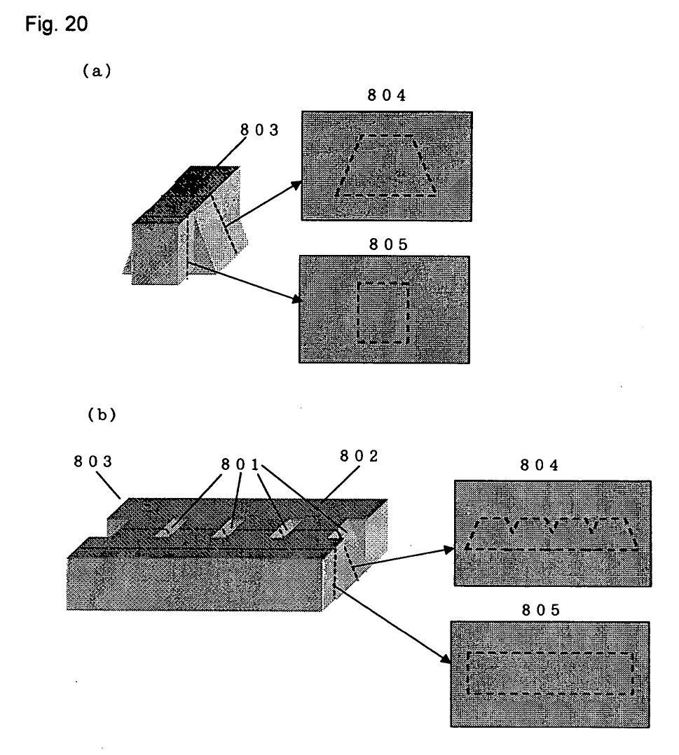

The semiconductor device of this invention is characterized in that a width increases from the uppermost side to the substrate side in the source/drain region, and the width defines a width in a given cross section perpendicular to the plane of the substrate (insulating film )509 in the source/drain region and to the channel current flow direction. The width may increase from the uppermost side to the substrate side in any cross section in the source/drain region. The source/drain region may have the same or different cross-sectional shapes in different positions. For example, as shown in FIG. 20(a), the region may have a shape where in the first cross section 804, the above width increases from the uppermost side to the substrate side while in the second cross section 805, a cross-sectional shape is rectangular.

### Embodiment 2

The second embodiment of this invention relates to a semiconductor device having a multi-structural MISFET. A multi-structural MISFET has a configuration where within one transistor, a plurality of protruding semiconductor regions are aligned in parallel in a direction perpendicular to a channel current flow direction and a gate electrode 501 is a conductor interconnection striding over the plurality of protruding semiconductor regions.

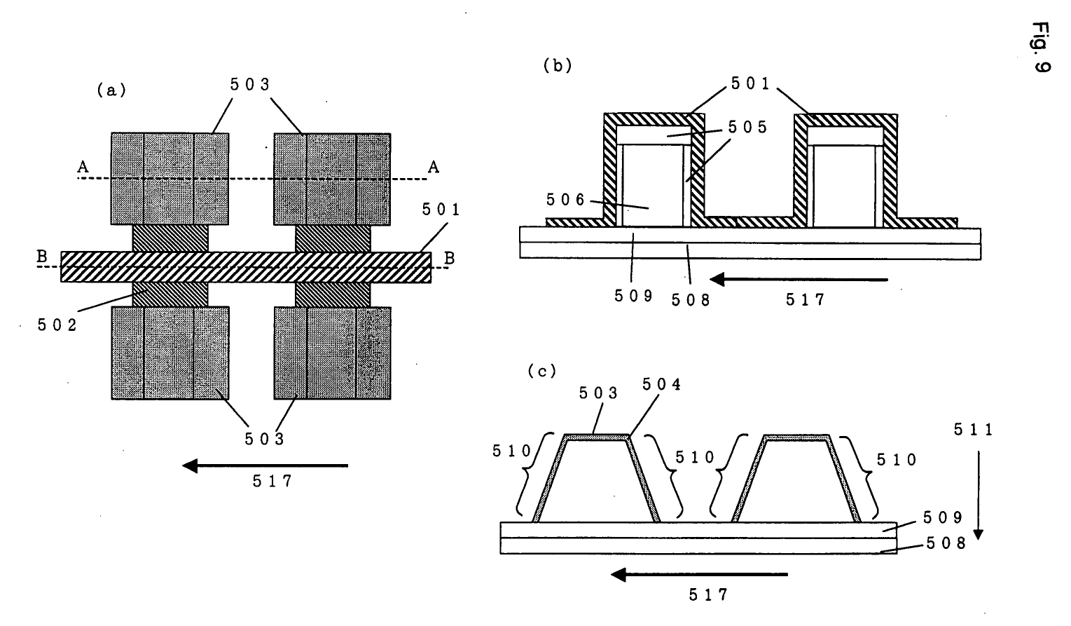

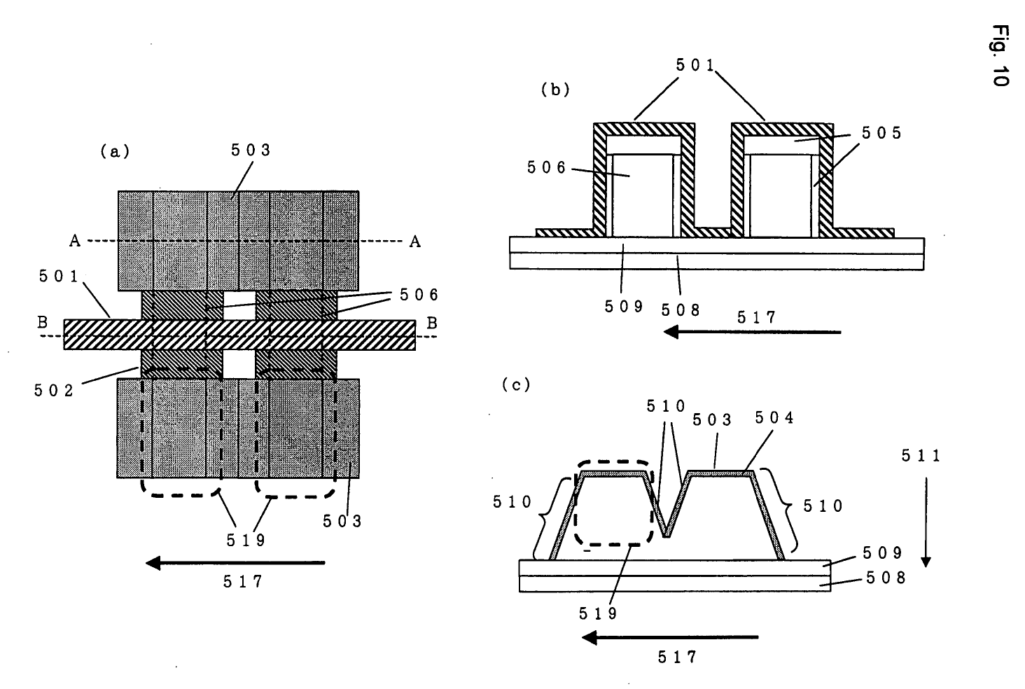

FIGS. 9(a) and 10(a) are plan views of a semiconductor device having an MISFET. FIGS. 9(b) and 10(b) are cross-sectional view of the semiconductor devices taken on line B-B in FIGS. 9(a) and 10(a), respectively. FIGS. 9(c) and 10(c) are cross-sectional views of the semiconductor devices taken on line A-A in FIGS. 9(a) and FIG. 10(a), respectively.

In the MISFET in FIG. 9, a plurality of protruding semiconductor regions 506 (only two in this figure) are disposed in a direction 517 perpendicular to a channel current flow direction, and a plurality of paired source/drain regions 503 (only two pairs in this figure) are disposed such that each pair sandwiches one of the plurality of protruding semiconductor regions 506. Each source/drain region has a taper shape 510.

In an MISFET in FIG. 10, a plurality of (only two shown in this figure) protruding semiconductor regions 506 are aligned as in FIG. 9, a common source/drain region 503 sandwiches these protruding semiconductor region 506, and one paired source/drain region 503 is formed in one MISFET. The source/drain region 503 has a plurality of convexes 519. In each convex 519, a cross-sectional area increases from the uppermost side to the substrate side (in the direction of the arrow 511) in the source/drain region. Herein, a cross-sectional area refers to a cross-sectional area of the source/drain region in a given plane parallel with the plane of the substrate (insulating film) 509. In FIG. 10, the plurality of convexes 519 in the source/drain region 503 are formed in the alignment direction 517 of the semiconductor regions 506 at the same intervals as the semiconductor regions 506, and in the alignment direction of the semiconductor regions 506, one convex 519 is parallel with one semiconductor region 506. Each concavity and convexity portion 519 in the source/drain region has a shape corresponding to the taper shape 510 of the source/drain region in the single-structural MISFET.

As shown in FIG. 9, in a multi-structural MISFET having an individual separate source/drain region in both sides of each protruding semiconductor region, each source/drain region can also have a similar shape to that in a single type MISFET. As shown in FIG. 10, in a multi-structural MISFET having a common source/drain region sandwiching protruding semiconductor regions, a concavity and convexity portion constituting the source/drain region can also have a shape corresponding to that in a single type MISFET. Each concavity and convexity portion may have the same or different shapes and may be contact each other on the insulating film 509.

Each of the source/drain regions or the concavity and convexity portions in the source/drain regions in the multi-structural MISFET may have a plurality of curve or taper shapes. Alternatively, a part of the region or the concavity and convexity portion may have a plane parallel with the substrate or a plane perpendicular to the substrate.

In such a multi-structural MISFET, one protruding semiconductor region has an individual source/drain region or a common large source/drain region, and a large surface area is silicided, so that a parasitic resistance in the MISFET is reduced. It, therefore, results in reduction of a contact resistance and facilitates alignment of the contact hole over the source/drain region.

The multi-structural MISFET has a plurality of protruding semiconductor regions in which lateral sides perpendicular to a substrate plane is used as a channel width, so that a plane area required by each channel width can be reduced, which is advantageous in size reduction of a device. This multi-structure can control a channel width by the number of the protruding semiconductor regions even when a plurality of transistors with different channel widths are formed in one chip. Thus, uniformity in device properties can be ensured by making the protruding semiconductor regions having an equal height. In the light of uniform device properties and processability, the plurality of concave semiconductor regions in one transistor have an equal width in the lower part of the gate electrode (a width parallel with the substrate plane and perpendicular to the channel length direction).

Manufacturing Process for a Semiconductor Device

A process for manufacturing a semiconductor device according to the present invention is characterized in that it comprises the step of processing a source/drain region into a curve or taper shape. There will be described (1) selective epitaxial growth and (2) etching as representative processes.

(1) Selective Epitaxial Growth

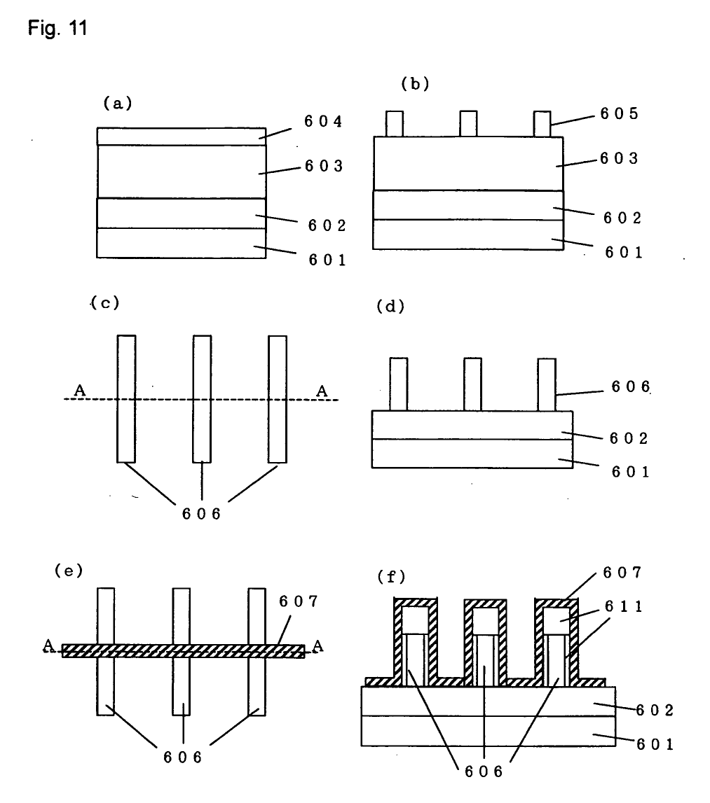

FIG. 11 illustrates, as an example, a manufacturing process for a semiconductor device having a multi-structural fin-type MISFET. First, bonding or SIMOX is employed to prepare an SOI substrate having a silicon wafer substrate 601, an SiO₂ oxide film 602 and a monocrystalline silicon film 603. Then, on the surface of the SOI substrate is formed an SiO₂ film 604 by thermal oxidation. FIG. 11(a) is a cross-sectional view of the substrate. Next, a dopant for forming a channel forming region is ion-implanted via the SiO₂ film 604. Then, the SiO₂ film 604 is etched off.

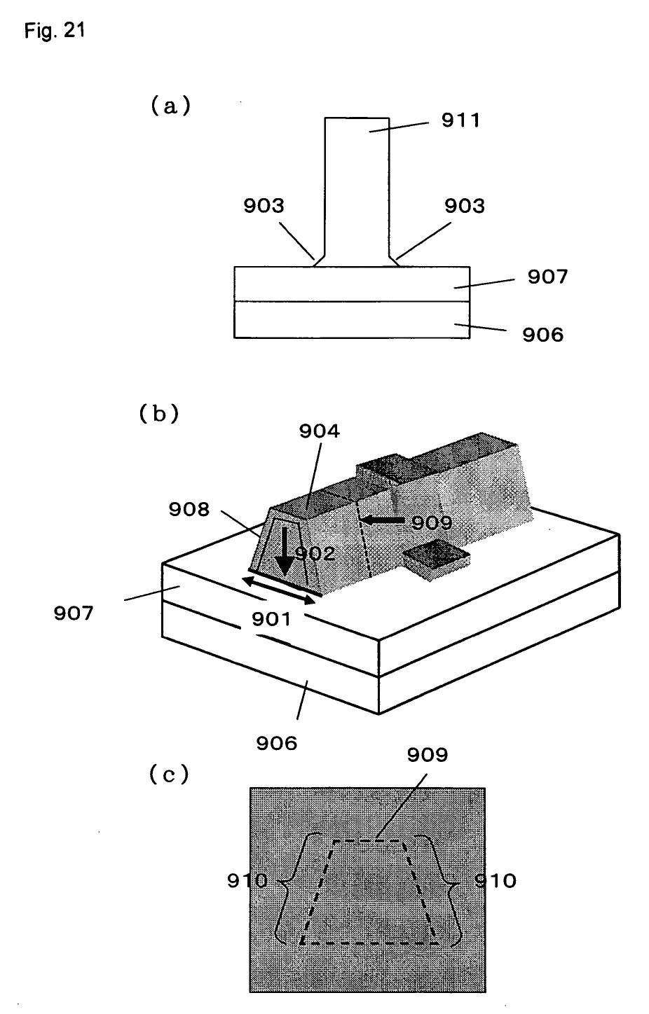

Then, a photoresist is applied over the whole surface of the monocrystalline silicon film 603, and then a resist mask 605 is formed by photolithography. FIG. 11(b) shows its cross section. Next, using the resist mask 605 as an etching mask, the monocrystalline silicon film 603 is anisotropically dry-etched. Subsequently, the resist mask 605 is removed to form a protruding semiconductor region 606 with a given height on the SiO₂ film 602. Here, depending on the etching conditions, the upper surface or the lateral sides of the protruding semiconductor region 606 may not be flat and fine protrusions may be formed. For example, in FIG. 21(a), a fine {111} plane 903 is formed on the border between the semiconductor region 911 and the substrate (SiO₂ film) 907. The fine plane may influence the shape of a source/drain region during selective epitaxial growth.

FIG. 11(c) is a plan view of a protruding semiconductor region. FIG. 11(d) is a cross-sectional view of the protruding semiconductor region 606 taken on line A-A in FIG. 11(c). Then, a thin SiO₂ film (gate insulating film 611) is formed on the surface (lateral sides) of the protruding semiconductor region 606 of monocrystalline silicon by thermal oxidation. Next, a polysilicon film is formed on the SiO₂ film 611 by CVD, is made conductive by dopant diffusion and is then selectively etched in a given pattern to form a gate electrode 607. FIG. 11(e) shows a plan view of the semiconductor device. FIG. 11(f) is a cross-sectional view of the protruding semiconductor region 606 taken on line A-A in FIG. 11(e).

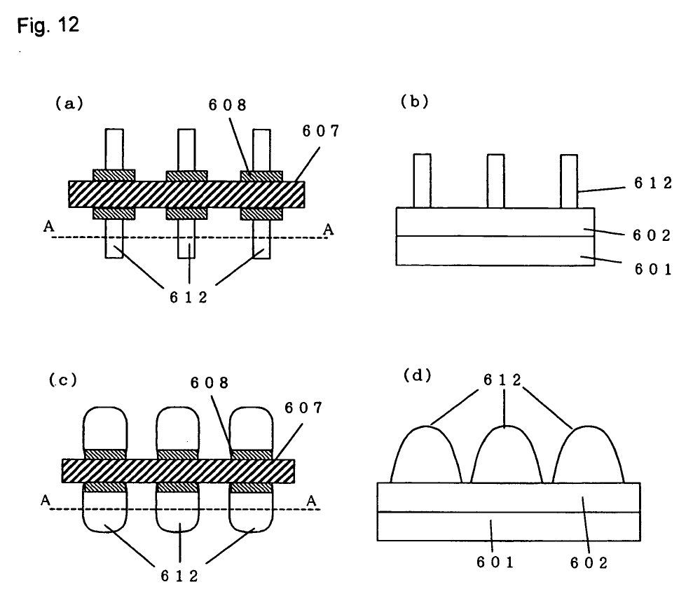

Then, extension ion implantation is conducted. After depositing a silicon oxide film by CVD, it is etched back by, for example, RIE to form a gate sidewall 608. FIG. 12(a) is a plan view of the semiconductor device. FIG. 12(b) is a cross-sectional view of the source/drain region 612 taken on line A-A in FIG. 12(a). Next, a source/drain region 612 is selectively epitaxially grown. A cross section may be the same or different between the source/drain region 612 before the selective epitaxial growth and the protruding semiconductor region in which a channel is formed. Herein, a cross section refers to a surface perpendicular to the substrate (insulating film) 602 and perpendicular to a channel current flow direction.

FIG. 12(c) illustrates an example of a manufacturing process where the source/drain region in FIG. 12(a) is selectively epitaxially grown such that a surface of the slope does not have a particular crystal face. As used herein, the term “a particular crystal face” refers to a plane which is not parallel with or perpendicular to the substrate (SiO₂ film) 602 and can be definitely recognized on the surface of a slope or a concavity and convexity portion. For example, when the growth conditions such as material supply is changed to competitively grow many fine crystal faces instead of preferentially growing a particular crystal face, a generally curved source/drain region is formed without a large crystal face in its surface as shown in FIG. 12(c). FIG. 12(c) is a plan view of the semiconductor device. In FIG. 12(c), since selective epitaxial growth is completed in a short period, adjacent source/drain regions do not become into contact, and both sides of each protruding semiconductor region 606 have individual source/drain regions. In the structure, the slope has a curved shape without a particular crystal face in its surface. FIG. 12(d) is a cross-sectional view of the source/drain region 612 taken on line A-A in FIG. 12(c).

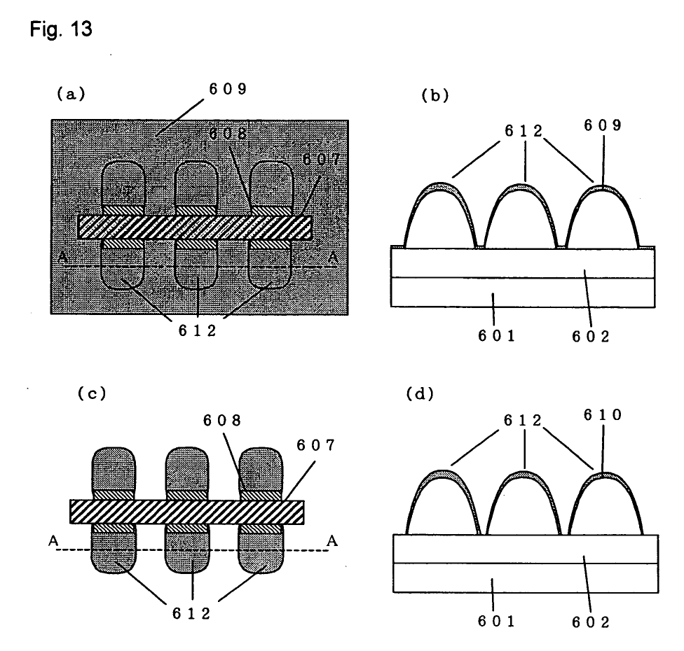

Next, a dopant is implanted to the source/drain region 612 after the selective epitaxial growth. The ions can be implanted from an oblique or vertical direction. A semiconductor device of this invention can be more readily ion-implanted than a conventional fin-type MISFET having lateral sides perpendicular to a substrate. Then, on the source/drain region 612 is deposited a metal layer 609 by sputtering. FIG. 13(a) is a plan view of this semiconductor device. FIG. 13(b) is a cross-sectional view of the source/drain region 612 taken on line A-A in FIG. 13(a). In the manufacturing process of this invention, the source/drain region 612 have a curved or taper shape, so that a metal layer 609 can be deposited in a wide area. The metal is preferably at least one selected from the group consisting of Ti, Co, Ni, Pt, Pd, Mo, W, Zr, Hf, Ta, Ir, Al, V and Cr. Next, the metal is reacted with silicon by annealing to form a stable silicide 610. Then, the unreacted metal layer is removed by wet etching. FIG. 13(c) is a plan view of the semiconductor device after the wet etching. FIG. 13(d) is a cross-sectional view of the source/drain region 612 taken in line A-A in FIG. 13(c). An annealing temperature may be a desired temperature, depending on the type of the metal layer. For example, when using Ni as a metal layer, it is preferably 400 to 600° C., and when Co is used, it is preferably 600 to 800° C. The annealing can be conducted in several steps, and the annealing may be interrupted by wet etching. Examples of a silicide material formed after the annealing include TiSi, TiSi₂, CoSi, CoSi₂, NiSi, NiSi₂ and Ni₂Si.

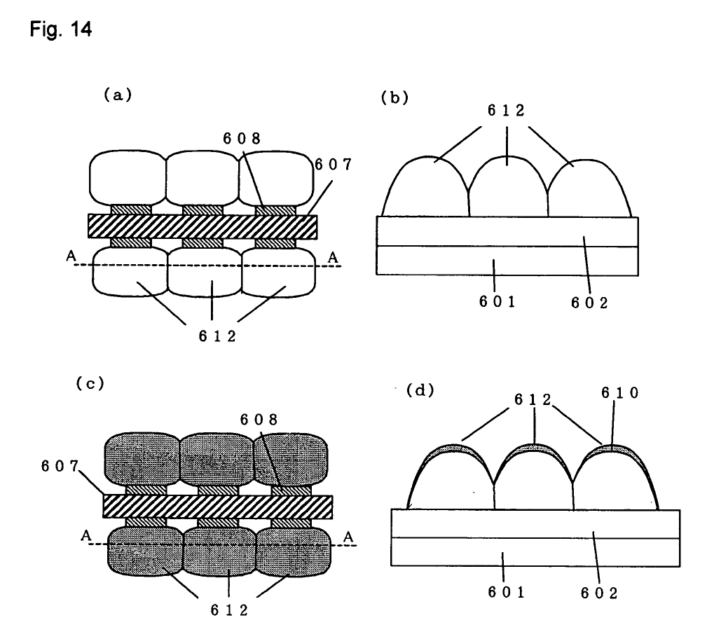

There will be described an example of a manufacturing process where the source/drain region 612 in FIG. 12(a) is selectively epitaxially grown for a long period. FIG. 14(a) is a plan view of a semiconductor device. In FIG. 14(a), since selective epitaxial growth is conducted for a long time, there is formed a source/drain region having a common concavity and convexity portion to a plurality of semiconductor regions and sandwiching the plurality of semiconductor regions. Each concavity and convexity portion does not have a particular crystal face in its surface. Thus, in the example shown in FIG. 14(a), the source/drain region 612 has a curved structure. FIG. 14(b) is a cross-sectional view of the source/drain region 612 taken on line A-A in FIG. 14(a). FIG. 14(c) is a plan view of a semiconductor device prepared by implanting ions, depositing a metal layer, annealing, removing the unreacted metal to the semiconductor device of FIG. 14(a) and finally forming a silicide film 610 on the source/drain region 612. FIG. 14(d) is a cross-sectional view of the source/drain region 612 taken on line A-A in FIG. 14(c). Thus, in the semiconductor device having a common source/drain region, a time for selective epitaxial growth may be appropriately determined, depending on the operation conditions such as a temperature and a material gas flow rate.

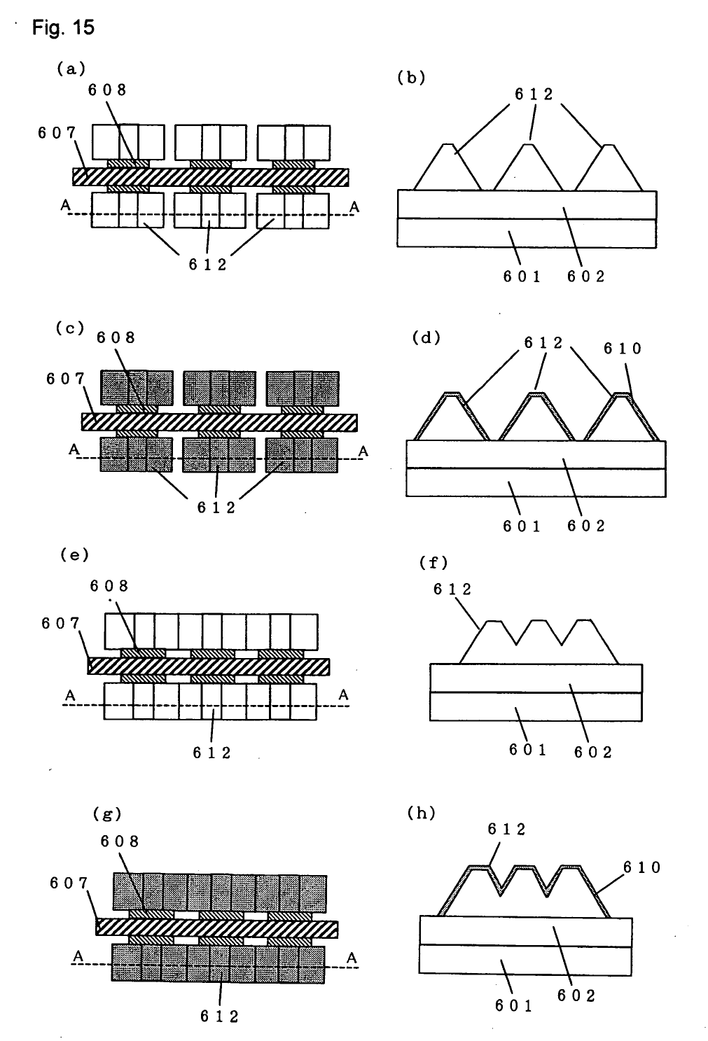

FIG. 15(a) illustrates an example of a manufacturing process where the semiconductor device shown in FIG. 12(a) is selectively epitaxially grown such that a slope has at least a particular crystal face in its surface. FIG. 15(a) is a plan view of the semiconductor device after the selective epitaxial growth for a short period. In the source/drain region in FIG. 15(a), a particular crystal face is preferentially grown to consequently give a taper shape. In this example, a fine {111} plane 903 shown in FIG. 21(a) is preferentially grown. When a particular crystal face is preferentially grown, it is preferable that substantially only two (one in one side) crystal faces 910 are formed in a cross section 909 which is parallel with a width direction 901 of the source/drain region in the slope and with the direction 902 from the uppermost side to the substrate side and intersects the uppermost part 904 as shown in FIGS. 21(b) and (c); substantially four (two in one side) faces 510 are formed as shown in FIG. 8(c); or up to about eight (four in one side) faces are formed. More preferably, two (one in one side) or four (two in one side) faces are formed. Although FIG. 21 shows a semiconductor device having a single-structural MISFET, a width direction 901 of the source/drain region and a direction 902 from the uppermost side to the substrate side are also defined in a multi-structural MISFET as in the single-structural MISFET.

Since the selective epitaxial growth is completed in a short period, adjacent source/drain regions are not in contact, and both sides of each protruding semiconductor region have individual source/drain regions. FIG. 15(b) is a cross-sectional view of the source/drain region 612 taken on line A-A in FIG. 15(a). Then, as described for FIGS. 13(a) to (d), the semiconductor device in FIG. 15(a) is subjected to dopant implantation, metal layer deposition, annealing and unreacted metal removal. FIG. 15(c) is a plan view of the semiconductor device after removing the unreacted metal layer. FIG. 15(d) is a cross-sectional view of the source/drain region 612 taken in line A-A in FIG. 15(c).

FIG. 15(e) is a plan view of a semiconductor device when the above selective epitaxial growth is conducted for a long period. FIG. 15(f) is a cross-sectional view of the source/drain region 612 taken on line A-A in FIG. 15(e). Because of the longer selective epitaxial growth in the FIG. 15(e), there is formed a source/drain region having a concavity and convexity portion common to a plurality of semiconductor regions and sandwiching the plurality of semiconductor regions. The source/drain region FIG. 15(e) has a taper shape as a result of preferential growth of a particular crystal face. FIG. 15(g) is a plan view of the semiconductor device after the semiconductor device is subjected to dopant implantation, metal layer deposition, annealing and unreacted metal removal to the semiconductor device in FIG. 15(e). FIG. 15(h) is a cross-sectional view of the source/drain region 612 taken on line A-A in FIG. 15(g).

The selective epitaxial growth can be conducted using a CVD apparatus. Main material gases used may include disilane gas (Si₂H₂) and monosilane gas (SiH₄). The doping may be conducted using a gas such as phosphine (PH₃) and diborane (B₂H₆).

(2) Etching Process

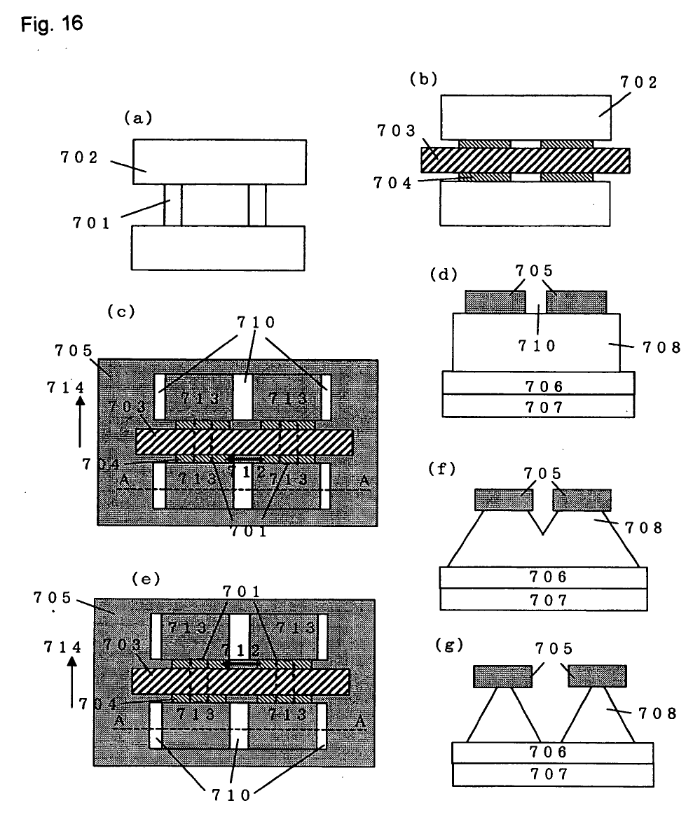

As described for the selective epitaxial growth, on an SiO₂ film are formed a plurality of protruding semiconductor regions 701 and protruding semiconductor regions 702 with a given height. FIG. 16(a) is a plan view of these semiconductor regions. The protruding semiconductor regions 702 may have any shape without being limited to a cuboid, as long as they protrude above the substrate and sandwich all of the semiconductor regions 701.

Then, as described for the selective epitaxial growth, a gate electrode 703 is formed, extension ion implantation is conducted and a gate sidewall 704 is formed (FIG. 16(b)). Next, after forming a resist mask 705 over the whole surface, photolithography is used to form a mask layer 705 having openings 710 which are aligned alternately with the semiconductor regions 701 in a direction 712 of alignment of the semiconductor regions 701 on a source/drain region 708. When forming the mask layer 705 as described above, mask layers 713 are formed on the source/drain region on the extension of the channel current flow direction 714 in the semiconductor regions 701, and mask openings 710 are formed between the mask layers 713. The openings may be formed from one end to the other end over the source/drain region in the channel current flow direction 714 (FIGS. 16(c) and (e)), and may not be necessarily formed from one end to the other end. The openings may have various shapes such as a rectangle, a square, a circle, an ellipse, a curve and a polygon. FIG. 16(c) is a plan view of the semiconductor device. FIG. 16(d) is a cross-sectional view of the source/drain region 708 taken on line A-A in FIG. 16(c).

The resist mask is used as an etching mask in etching. When etching as a mask in which openings are not formed from one end to the other end of the source/drain region in, there is formed, for example, a source/drain region as shown in FIG. 20(b). In FIG. 20(b), the taper shapes 801 correspond to the source/drain region etched, in which mask openings 710 have been formed before the etching. The protrusion 802 corresponds to the source/drain region not etched because of the mask layer 705. The surface having the taper shapes 801 and the cross section of the protrusion 802 correspond to 804 and 805, respectively. FIG. 16(e) is a plan view of the semiconductor device after etching. The etching may be conducted by wet or dry etching.

In wet etching, a solution such as a KOH solution and a TMAH solution is used. In the etching, known conditions may be employed in terms of, for example, a temperature, a solution concentration and an etching period. For example, in wet etching of a semiconductor region in which a (100) plane is a plane direction parallel with the substrate (SiO₂ oxide film) 706, an etching rate in a (111) plane is extremely lower than any other crystal face. Thus, the source/drain region 708 having a taper shape of 54.7° is finally formed.

In dry etching, the source/drain region 708 having a taper shape with a given inclination angle can be formed by sequentially conducting isotropic dry etching and anisotropic dry etching using a resist mask as an etching mask. An inclination angle in the taper shape can be controlled by adjusting an etching ratio between isotropic and anisotropic dry etching. The dry etching conditions may be those known in the art.

Etching for a long period can provide an MISFET where both sides of each protruding semiconductor region have individual source/drain region 708s, as shown in FIG. 16(g). Etching for a short period can provide an MISFET having a common source/drain region sandwiching individual protruding semiconductor regions, as shown in FIG. 16(f). An etching time for preparing the former semiconductor device varies depending on the operation conditions such as a temperature and a material gas flow rate, and may be appropriately determined.

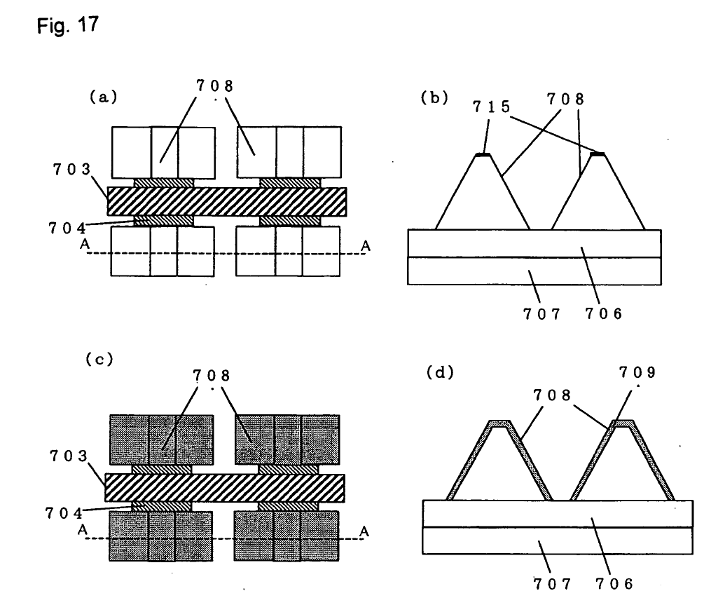

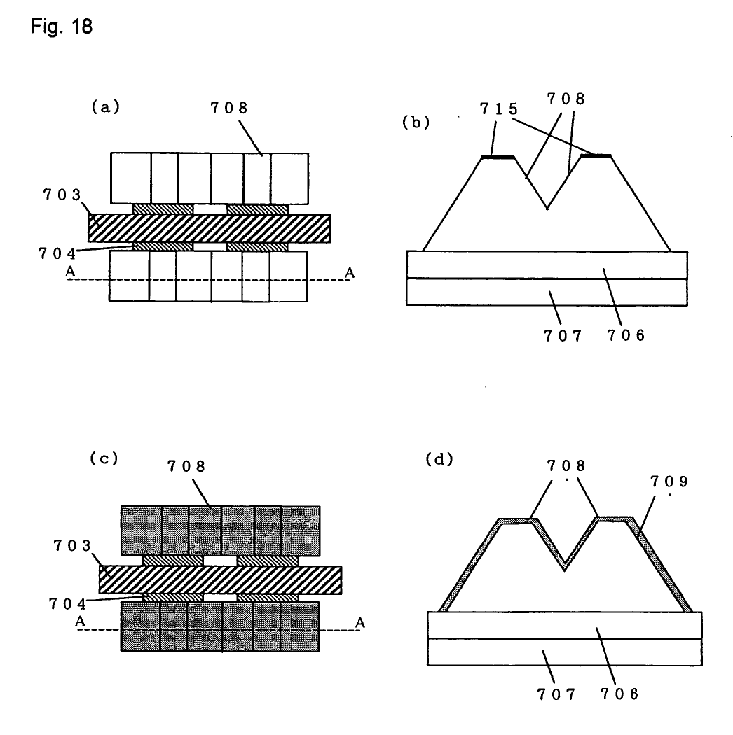

Next, the etching mask is removed. FIGS. 17(a) and 18(a) are plan views showing semiconductor devices in FIGS. 16(f) and (g) after removal of the etching mask, respectively. FIGS. 17(b) and 18(b) are cross-sectional views of the source/drain regions 708 taken in line A-A in FIGS. 17(a) and 18(a), respectively. It is required that in the source/drain region after etching, at least the largest width is larger than the width of the semiconductor region 701, and a width of the upper surface 715 in the source/drain region may be smaller than the width of the semiconductor region 701. Next, after implanting a dopant as described for the selective epitaxial growth, a silicide film 709 is formed on the source/drain region 708. FIGS. 17(c) and 18(c) are plan views of semiconductor devices having the suicide film 709 in the source/drain regions 708 in FIGS. 17(a) and 18(a), respectively. FIGS. 17(d) and 18(d) are cross-sectional views of the source/drain regions 708 taken on line A-A in FIGS. 17(c) and 18(c), respectively.

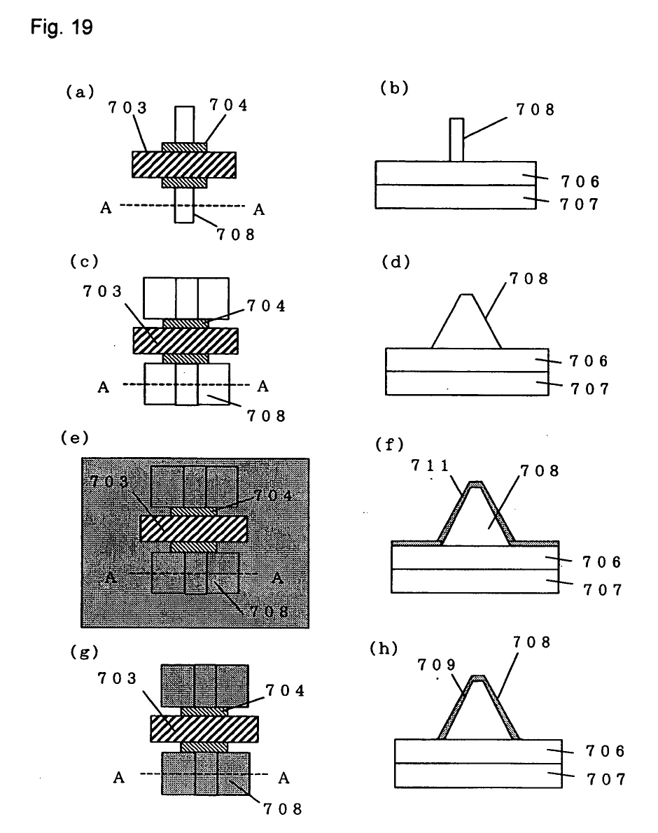

A semiconductor device having a single-structural MISFET can be also manufactured as described above for a semiconductor device having a multi-structural MISFET. A difference from the process for manufacturing a semiconductor device having a multi-structural MISFET is that one protruding semiconductor region is first formed on a substrate. FIG. 19 illustrates a process for manufacturing a semiconductor device having a single-structural MISFET. First, a protruding semiconductor region is formed. When forming a slope in a source/drain region by etching, a semiconductor region to be a source/drain region is formed such that it has a width larger than that of a protruding semiconductor region where a channel is formed. Next, on the semiconductor region are formed a gate electrode 703 and a gate sidewall 704. FIG. 19(a) is a plan view of the semiconductor device. FIG. 19(b) is a cross-sectional view of the protruding semiconductor region 708 taken on line A-A in FIG. 19(a). Then, a source/drain region 708 is grown by anisotropic selective epitaxial growth. FIG. 19(c) is a plan view of the semiconductor device. FIG. 19(d) is a cross-sectional view of the source/drain region 708 taken on line A-A in FIG. 19(c). Next, on the semiconductor device is deposited a metal layer 711. FIG. 19(e) is a plan view of the semiconductor device. FIG. 19(f) is a cross-sectional view of the source/drain region 708 taken on line A-A in FIG. 19(e). Subsequently, after forming a silicide film 709 by annealing, the unreacted metal layer is removed. FIG. 19(g) is a plan view of the semiconductor device. FIG. 19(h) is a cross-sectional view of the source/drain region 708 taken on line A-A in FIG. 19(g).

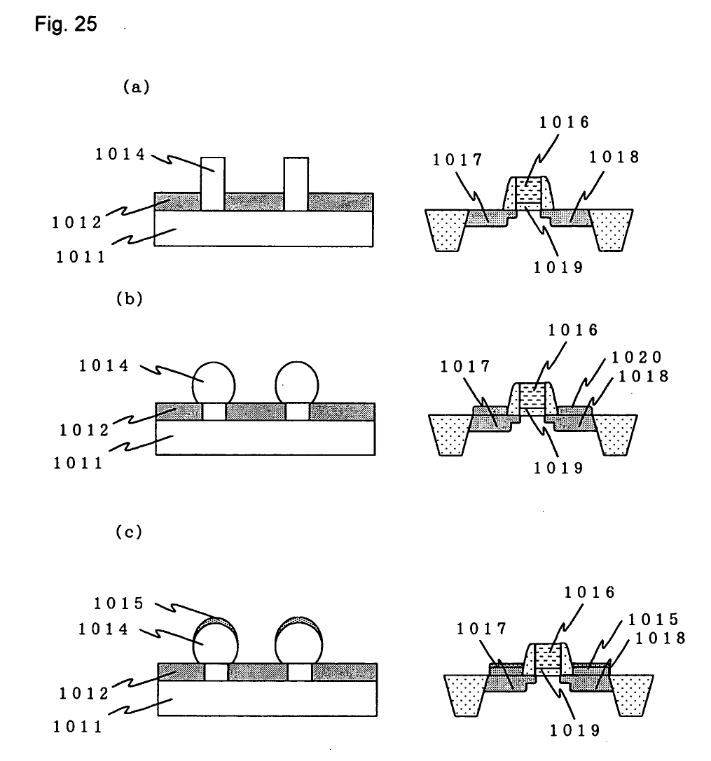

In the present invention, there may be prepared a semiconductor device having a combination of a fin-type MISFET and a planar type (plane type) MISFET. FIG. 25 illustrates an example of the manufacturing process for a semiconductor device. FIG. 25(a) illustrates the state after forming a protruding semiconductor region for a fin-type MISFET and a source/drain region (1017, 1018) for a planar type MISFET. FIG. 25(b) is the state after selective epitaxial growth of the protruding semiconductor region and the source/drain region 1017, 1018 in FIG. 25(a). By the selective epitaxial growth, a slope is formed in the source/drain region in the fin-type MISFET while the elevated source/drain region is formed in the planar type MISFET. FIG. 25(c) illustrates the state after forming a silicide film 1015 on the source/drain region 1014 and the elevated source/drain region 1020 in the semiconductor device of FIG. 25(b). Thus, according to this invention, a fin-type and a planar type MISFETs can be simultaneously manufactured, resulting in simplification of a production process.

1. A semiconductor device comprising a protruding semiconductor region formed on a substrate, a protruding source/drain region sandwiching the semiconductor region and a gate electrode formed at least on lateral sides of the semiconductor region via an insulating film,
wherein the source/drain region has a slope in which at least the largest width is larger than a width of the semiconductor region and width continuously increases from the uppermost side to the substrate side in the source/drain region, and a silicide film is formed on the surface of the slope.

2. A semiconductor device comprising a plurality of protruding semiconductor regions formed on a substrate, a plurality of source/drain regions sandwiching the semiconductor regions and a gate electrode formed at least on lateral sides of the semiconductor regions via an insulating film,
wherein the plurality of semiconductor regions are aligned in a direction perpendicular to a channel current flow and in parallel with each other, and the gate electrode strides over the plurality of semiconductor regions and extends in a direction perpendicular to the channel current flow,
wherein the source/drain regions have slopes in which at least the largest width is larger than a width of the semiconductor region and width continuously increases from the uppermost side to the substrate side in the source/drain regions, and a silicide film is formed on the surface of the slopes.

3. A semiconductor device comprising a plurality of protruding semiconductor regions formed on a substrate, a paired protruding source/drain region which is common to the plurality of semiconductor regions and sandwiches the plurality of semiconductor regions, and a gate electrode formed at least on lateral sides of the plurality of semiconductor regions via an insulating film,
wherein the plurality of semiconductor regions are aligned in a direction perpendicular to a channel current flow and in parallel with each other, and the gate electrode strides over the plurality of semiconductor regions and extends in a direction perpendicular to the channel current flow,
wherein the source/drain region has a concavity and convexity portion in which a cross-sectional area continuously increases from the uppermost side to the substrate side, and a silicide film is formed on the surface of the concavity and convexity portion.

4. The semiconductor device as claimed in claim 3, wherein the concavity and convexity portion are formed in the direction of alignment of the plurality of semiconductor regions at the same regular intervals as the plurality of semiconductor regions such that the semiconductor regions are in parallel with the concavity and convexity portion.

5. The semiconductor device as claimed in any of claims 1 to 4, wherein the uppermost side of the source/drain region(s) is parallel with a plane of the substrate and a silicide film is formed on the uppermost side.

6. The semiconductor device as claimed in claim 1 or 2, wherein the whole of the source/drain region(s) is composed from the slope(s) having a silicide film on its surface.

7. The semiconductor device as claimed in claim 1 or 2, wherein a width of the slope(s) in the source/drain region(s) increases from the uppermost side to the substrate side in a constant rate.

8. The semiconductor device as claimed in claim 3, wherein the cross-sectional area of the concavity and convexity portion increases from the uppermost side to the substrate side in a constant rate.

9. A process for manufacturing a semiconductor device comprising a field effect transistor having a protruding semiconductor region in whose lateral sides a channel is formed, comprising
(a) forming a protruding source/drain region sandwiching the protruding semiconductor region with a gate electrode by selective epitaxial growth to make a slope in which a width of the source/drain region is larger than a width of the semiconductor region and continuously increases from the uppermost side to the substrate side in the source/drain region, and (b) forming a silicide film on the surface of the slope.

10. A process for manufacturing a semiconductor device comprising a field effect transistor having a plurality of protruding semiconductor regions in whose lateral sides a channel is formed, comprising
(a) forming a gate electrode striding over the plurality of protruding semiconductor regions, then forming a plurality of protruding source/drain regions sandwiching the plurality of semiconductor regions by selective epitaxial growth to make slopes in which a width of the source/drain regions is larger than a width of the semiconductor regions and continuously increases from the uppermost side to the substrate side in the source/drain regions, and (b) forming a silicide film on the surface of the slopes.

11. A process for manufacturing a semiconductor device comprising a field effect transistor having a plurality of protruding semiconductor regions in whose lateral sides a channel is formed, comprising
(a) forming a gate electrode striding over the plurality of protruding semiconductor regions, then forming a plurality of protruding source/drain regions sandwiching the plurality of semiconductor regions by selective epitaxial growth until adjacent source/drain regions come into contact each other to make a concavity and convexity portion where a cross-sectional area of the source/drain regions continuously increase from the uppermost side to the substrate side in the source/drain regions during the selective epitaxial growth, and (b) forming a silicide film on the surface of the concavity and convexity portion.

12. The process for manufacturing a semiconductor device as claimed in claim 9 or 10, wherein the slope(s) is formed by selective epitaxial growth in substantially up to eight crystal faces in a cross section which is in parallel with the width direction and with the direction from the uppermost side to the substrate side of the source/drain region(s) and intersects with the uppermost side.

13. The process for manufacturing a semiconductor device as claimed in claim 11, wherein the concavity and convexity portion are formed by selective epitaxial growth in substantially up to eight crystal faces in a cross section which is in parallel with the width direction and with the direction from the uppermost side to the substrate side of the source/drain regions and intersects with the uppermost side.

14. The process for manufacturing a semiconductor device as claimed in claim 9 or 10, wherein the slope(s) is formed by selective epitaxial growth as a substantially curve in a cross section which is in parallel with the width direction and with the direction from the uppermost side to the substrate side of the source/drain region(s) and intersects with the uppermost side.

15. The process for manufacturing a semiconductor device as claimed in claim 11, wherein the concavity and convexity portion are formed by selective epitaxial growth as a substantially curve in a cross section which is in parallel with the width direction and with the direction from the uppermost side to the substrate side of the source/drain regions and intersects with the uppermost side.

16. A process for manufacturing a semiconductor device comprising a field effect transistor having a protruding semiconductor region in whose lateral sides a channel is formed, comprising,
(a) forming a gate electrode on the protruding semiconductor region and then etching a protruding source/drain region sandwiching the semiconductor region and having a larger width than the width of the semiconductor region, to make a slope in which a width of the source/drain region is larger than a width of the semiconductor region and continuously increases from the uppermost side to the substrate side in the source/drain region, and (b) forming a silicide film on the surface of the slope.

17. A process for manufacturing a semiconductor device comprising a field effect transistor having a plurality of protruding semiconductor regions in whose lateral sides a channel is formed, comprising,
(a) forming a gate electrode striding over the plurality of protruding semiconductor regions, forming a paired protruding source/drain region sandwiching the plurality of semiconductor regions, and then forming a mask film having a plurality of openings alternately with the plurality of semiconductor regions along the alignment direction of the semiconductor regions on the source/drain region, (b) conducting etching using the mask film to make the paired source/drain region into a plurality of source/drain regions mutually separated sandwiching the plurality of semiconductor regions and during the etching, making slopes in which a width of the source/drain regions is larger than a width of the semiconductor regions and continuously increases from the uppermost side to the substrate side in the source/drain regions, and (c) forming a silicide film on the slopes.

18. A process for manufacturing a semiconductor device comprising a field effect transistor having a plurality of protruding semiconductor regions in whose lateral sides a channel is formed, comprising,
(a) forming a gate electrode striding over the plurality of protruding semiconductor regions, forming a paired protruding source/drain region sandwiching the plurality of semiconductor regions, and then forming a mask film having a plurality of openings alternately with the plurality of semiconductor regions along the alignment direction of the semiconductor regions on the source/drain region, (b) conducting etching using the mask film to make a concavity and convexity portion in which cross-sectional area continuously increases from the uppermost side to the substrate side in the source/drain region, and (c) forming a silicide film on the concavity and convexity portion.

19. The process for manufacturing a semiconductor device as claimed in any of claims 16 to 18, wherein the etching is wet etching.

20. The semiconductor device as claimed in any of claims 1 to 3, wherein the substrate is an insulating film layer, on which the protruding semiconductor region(s) and the protruding source/drain region(s) are formed.

21. The semiconductor device as claimed in any of claims 1 to 3, wherein the substrate is an interlayer insulating film, and
the protruding semiconductor region(s) and the protruding source/drain region(s) are parts of the semiconductor layer formed under the interlayer insulating film, which penetrates the interlayer insulating film and protrudes above the interlayer insulating film.

22. The semiconductor device as claimed in any of claims 1 to 3, further comprising a planar type field effect transistor having a semiconductor region on whose upper surface a main channel is formed, and an elevated source/drain region.
